(19) United States
(12) Patent Application Publication
(10) Pub. No.: US 2020/0166843 A1
(43) Pub. Date: May 28, 2020

(54) PATTERN FORMING METHOD AND PROCESSING LIQUID

(71) Applicant: JSR CORPORATION, Tokyo (JP)

(72) Inventors: Makoto SHIMIZU, Tokyo (JP); Ryo KAWAJIRI, Tokyo (JP); Daigo ICHINOHE, Tokyo (JP)

(73) Assignee: JSR CORPORATION, Tokyo (JP)

(21) Appl. No.: 16/778,505

(22) Filed: Jan. 31, 2020

Related U.S. Application Data
(63) Continuation-in-part of application No. PCT/JP2018/028599, filed on Jul. 31, 2018.

(30) Foreign Application Priority Data
Aug. 4, 2017 (JP) 2017-151354

(51) Int. Cl. G03F 7/038; G03F 7/32; G03F 7/004; C08L 33/10

(52) U.S. Cl. CPC G03F 7/0382; C08L 33/10; G03F 7/0045; G03F 7/325

(57) ABSTRACT

A pattern forming method included applying a photoresist composition on a substrate to form a resist film on the substrate. The resist film is exposed. The exposed resist film is developed with a developer to form a pattern. The pattern is contacted with a processing liquid to process the pattern. The photoresist composition includes a polymer [A] and a radiation-sensitive acid generator [B]. The polymer includes a structural unit (I) including an acid-dissociable group that dissociates due to action of an acid. The polymer has solubility to the developer that reduces due to dissociation of the acid-dissociable group. The processing liquid exhibits acidity.

### CROSS-REFERENCE TO RELATED APPLICATIONS

The present application is a continuation-in-part application of International Application No. PCT/JP2018/028599, filed Jul. 31, 2018, which claims priority to Japanese Patent Application No. 2017-151354, filed Aug. 4, 2017. The contents of these applications are incorporated herein by reference in their entirety.

### BACKGROUND OF THE INVENTION

### Field of the Invention

The present invention relates to a pattern forming method and a processing liquid.

### Description of the Related Art

Along with the miniaturization of structures of various electronic devices such as semiconductor devices and liquid crystal devices, resist patterns in lithography are required to be finer. At present, fine resist patterns having a line width of about 90 nm can be formed using, for example, an ArF excimer laser. However, formation of finer resist patterns will be required in future.

As a technique to meet such a requirement, a technique using an organic solvent having a polarity lower than that of an aqueous alkaline solution as a developer is known, which improves the resolution of a conventional chemically-amplified photoresist composition using an existing system without increasing the number of steps (see, JP-A-2000-199953). More specifically, when a resist pattern is formed using an aqueous alkaline solution as a developer, it is difficult to form a fine resist pattern due to poor optical contrast, but in the case of this technique using an organic solvent, a fine resist pattern can be formed due to an increase in optical contrast.

However, when an organic solvent is used as a developer, there is a disadvantage that etching resistance is reduced due to the film loss of a resist film in a pattern forming step, and therefore a desired pattern cannot be obtained.

JP-A-2013-011833 discloses that when an organic solvent developer is used, a nitrogen-containing compound is added to the organic solvent developer for the purpose of reducing film loss and line width roughness (LWR). This technique can improve exposure latitude (EL) and LWR while maintaining performances, such as sensitivity and depth of focus (DOF), excellent.

### SUMMARY OF THE INVENTION

According to an aspect of the present invention, a pattern forming method includes applying a photoresist composition on a substrate to form a resist film on the substrate. The resist film is exposed. The exposed resist film is developed with a developer to form a pattern. The pattern is contacted with a processing liquid to process the pattern. The photoresist composition includes a polymer [A] and a radiation-sensitive acid generator [B]. The polymer includes a structural unit (I) including an acid-dissociable group that dissociates due to action of an acid. The polymer has solubility to the developer that reduces due to dissociation of the acid-dissociable group. The processing liquid exhibits acidity.

According to another aspect of the present invention, processing liquid includes at least one selected from the group consisting of hydrogen peroxide, carbonic acid, nitric acid, sulfuric acid, an organic acid, and an organic acid salt. The processing liquid exhibits acidity and is suitable for processing in a pattern forming method including: developing a resist film with a developer including an organic solvent and a basic compound; and performing processing of a pattern formed in the step of developing.

### DETAILED DESCRIPTION OF THE PREFERRED EMBODIMENTS

An embodiment of the present invention is directed to a pattern forming method including:

(1) forming a resist film on a substrate using a photoresist composition;

(2) exposing the resist film;

(3) developing the exposed resist film with a developer to form a pattern; and

(4) processing the pattern with a processing liquid, wherein

the photoresist composition contains a polymer [A] having a structural unit (I) including an acid-dissociable group that dissociates due to action of an acid and having solubility to the developer that reduces due to dissociation of the acid-dissociable group, and a radiation-sensitive acid generator [B], and

the processing liquid exhibits acidity.

In the pattern forming method, it is preferred that the developer contains an organic solvent and further contains a basic compound.

According to the embodiment of the pattern forming method of the present invention, the negative developer containing an organic solvent contains a basic compound, and the pattern is processed with a processing liquid exhibiting acidity, and therefore a pattern having reduced development defects can be formed while effects are obtained such as reduction in film loss in an exposed area, improvement in lithography characteristics such as dissolution contrast between an unexposed area and an exposed area in the development step, reduction in LWR, sensitivity and DOF. It is to be noted that the term “acid-dissociable group” used herein refers to a group that substitutes for a hydrogen atom of a polar group such as a carboxyl group, a hydroxyl group, an amino group, or a sulfo group and that dissociates due to the action of an acid.

The basic compound is preferably a nitrogen-containing compound, and is more preferably a compound represented by the following formula (1):

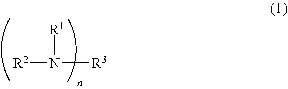

where R¹ and R² are each independently a hydrogen atom, a hydroxyl group, a formyl group, an alkoxy group, an alkoxycarbonyl group, a chain hydrocarbon group having 1 to 30 carbon atoms, an alicyclic hydrocarbon group having 3 to 30 carbon atoms, an aromatic hydrocarbon group having 6 to 14 carbon atoms, or a group obtained by combining two or more of these groups, R³ is a hydrogen atom, a hydroxyl group, a formyl group, an alkoxy group, an alkoxycarbonyl group, an n-valent chain hydrocarbon group having 1 to 30 carbon atoms, an n-valent alicyclic hydrocarbon group having 3 to 30 carbon atoms, an n-valent aromatic hydrocarbon group having 6 to 14 carbon atoms, or an n-valent group obtained by combining two or more of these groups, n is an integer of 1 or more, wherein when n is 2 or more, two or more R¹s and two or more R²s may be the same or different, respectively, and any two of R¹ to R³ may be linked to form a cyclic structure together with a nitrogen atom linked thereto.

When the nitrogen-containing compound has the above specific structure, film loss in an exposed area can further be reduced. Further, a pattern formed by this pattern forming method has a reduced LWR, sufficiently satisfies sensitivity, DOF, etc., and has few development defects.

In a preferred embodiment, the processing liquid contains at least one selected from the group consisting of hydrogen peroxide, carbonic acid, nitric acid, sulfuric acid, organic acids and organic acid salts. Further, the organic acid or organic acid salt is one or two organic acid selected from the group consisting of oxalic acid, citric acid, succinic acid, ethylenediaminetetraacetic acid, tartaric acid, salicylic acid, formic acid, acetic acid, propionic acid, butyric acid, valeric acid, caproic acid, caprylic acid, lauric acid, myristic acid palmitic acid, stearic acid, arachinic acid, benzoic acid, acrylic acid, adipic acid, malonic acid, malic acid, glycolic acid, phthalic acid, terephthalic acid, pimelic acid and fumaric acid, or a salt thereof.

The structural unit (I) preferably has a group represented by the following formula (2):

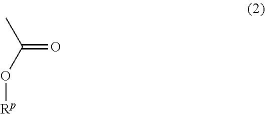

where R^{P} is an acid-dissociable group.

When the structural unit (I) has a group represented by the above formula (2), the acid-dissociable group dissociates due to the action of an acid so that a carboxyl group having a high polarity is generated in the exposed area of the resist film used in this pattern forming method. This carboxyl group and the nitrogen-containing compound contained in the developer interact so that solubility to the developer can further be reduced. Therefore, this pattern forming method can further reduce film loss in the exposed area. Further, a pattern formed by this pattern forming method has a reduced LWR, sufficiently satisfies sensitivity, DOF, etc., and has few development defects.

The structural unit (I) is preferably a structural unit represented by the following formula (3):

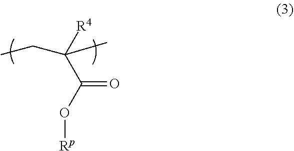

where R⁴ is a hydrogen atom, a methyl group, or a trifluoromethyl group, and R^{P} is the same as defined in the formula (2).

When the structural unit (I) has the above specific structure, the acid-dissociable group dissociates due to the action of an acid generated in an exposed area so that a carboxyl group is generated. This carboxyl group and the nitrogen-containing compound contained in the developer interact so that solubility to the developer can further be reduced. Therefore, this pattern forming method can further reduce film loss in the exposed area. Further, a pattern formed by this pattern forming method has a reduced LWR, sufficiently satisfies sensitivity, DOF, etc., and has few development defects.

The acid-dissociable group represented by R^{P} is preferably a group represented by the following formula (4):

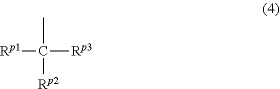

where R^{P1} to R^{p3} are each an alkyl group having 1 to 4 carbon atoms or an alicyclic hydrocarbon group having 4 to 20 carbon atoms, wherein some or all hydrogen atoms of the alkyl group or the alicyclic hydrocarbon group may be substituted, and R^{P2} and R^{P3} may be linked together to form a divalent alicyclic hydrocarbon group having 4 to 20 carbon atoms together with a carbon atom linked thereto.

When the acid-dissociable group represented by R^{p} in the above formulas (2) and (3) is a group having a specific structure represented by the above formula (4), the acid-dissociable group easily dissociates due to the action of an acid generated in an exposed area. As a result, this pattern forming method can further reduce the solubility of exposed area of the resist film to the developer so that film loss can further be reduced.

The organic solvent contained in the developer is preferably at least one selected from the group consisting of an ether-based solvent, a ketone-based solvent, and an ester-based solvent. When the organic solvent contained in the developer is at least one selected from the group consisting of an ether-based solvent, a ketone-based solvent, and an ester-based solvent, the solubility of an exposed area in the developer can further be reduced so that film loss can further be reduced.

Another embodiment of the present invention is also directed to a processing liquid exhibiting acidity and used for processing in a pattern forming method including:

developing a resist film with a developer containing an organic solvent and a basic compound; and

performing processing of a pattern formed in the developing.

The processing liquid makes it possible to form a pattern having reduced development defects while obtaining effects such as reduction in film loss in an exposed area, improvement in lithography characteristics such as dissolution contrast between an unexposed area and an exposed area in the developing, reduction in LWR, sensitivity and DOF, etc.

According to the resist pattern forming method of the present embodiment, it is possible to reduce film loss in the resist pattern forming and form a resist pattern having a reduced LWR, sufficiently satisfying sensitivity, DOF, etc., and having few development defects. Hereinafter, details of the embodiments of the present invention will be explained.

### <Pattern Forming Method>

A pattern forming method according to the present embodiment includes: (1) forming a resist film on a substrate using a photoresist composition; (2) exposing the resist film; (3) developing the exposed resist film with a developer to form a pattern; and (4) processing the pattern with a processing liquid, wherein the photoresist composition contains a polymer [A] having a structural unit (I) including an acid-dissociable group that dissociates due to action of an acid and having solubility to the developer that reduces due to dissociation of the acid-dissociable group and a radiation-sensitive acid generator [B], and the processing liquid exhibits acidity. Hereinbelow, each of the steps, the photoresist composition, and the developer will be described in detail.

### [Step (1)]

In this step, a photoresist composition used in the present embodiment is applied onto a substrate to form a resist film. As the substrate, a conventionally-known substrate such as a silicon wafer or a wafer coated with aluminum can be used. An organic or inorganic lower antireflective film disclosed in, for example, JP-B-6-12452 or JP-A-59-93448 may be formed on the substrate.

Examples of a method for applying the photoresist composition include spin coating, cast coating, and roll coating. It is to be noted that the formed resist film usually has a thickness of 0.01 μm to 1 μm, preferably 0.01 μm to 0.5 μm.

After the photoresist composition is applied, a solvent contained in the coated film may be vaporized by prebaking (PB), if necessary. The heating condition for PB is appropriately selected depending on the composition of the photoresist composition, but is usually about 30° C. to 200° C., preferably 50° C. to 150° C.

In order to prevent the influences of basic impurities etc. contained in an ambient atmosphere, a protective film disclosed in, for example, JP-A-5-188598 may be provided on the resist layer. Further, in order to prevent the outflow of an acid generating agent etc. from the resist layer, a protective film for immersion exposure disclosed in, for example, JP-A-2005-352384 may be provided on the resist layer. It is to be noted that these techniques can be used in combination.

### [Step (2)]

In this step, a desired area in the resist film formed in the step (1) is subjected to reduced projection exposure via a mask having a specific pattern and an immersion liquid used if necessary. For example, a desired area in the resist film may be subjected to reduced projection exposure via a mask having an isolated line pattern to form an isolated space pattern. Similarly, reduced projection exposure may be performed via a mask having a dot pattern to form a hole pattern. The exposure may be performed two or more times via a desired pattern and a mask pattern. When the exposure is performed multiple times, the exposure is preferably performed continuously. When the exposure is performed two or more times, for example, a desired area in the resist film is subjected to first reduced projection exposure via a line and space pattern mask, and is then continuously subjected to second reduced projection exposure so that lines intersect with an exposed area subjected to the first exposure. An exposed area subjected to the second exposure is preferably orthogonal to the exposed area subjected to the first exposure. When the exposed area subjected to the first exposure and the exposed area subjected to the second exposure are orthogonal to each other, a contact hole pattern can be formed in an unexposed area surrounded by the exposed area. Examples of the immersion liquid used for exposure include water and a fluorine-based inert liquid. The immersion liquid is preferably a liquid that is transparent to an exposure wavelength and has a temperature coefficient of refractive index as small as possible to minimize the distortion of an optical image projected onto the film. Particularly, when an exposure light source is ArF excimer laser light (wavelength: 193 nm), water is preferably used from the viewpoint of availability and ease of handling in addition to the above-described viewpoints.

Radiation used for exposure is appropriately selected depending on the kind of acid generator [B], and examples thereof include ultraviolet rays, far-ultraviolet rays, X-rays, and charged particle rays. Among them, far-ultraviolet rays typified by ArF excimer laser light (wavelength: 193 nm) and KrF excimer laser light (wavelength: 248 nm) are preferred, and an ultrafine patterning of 32 nm or less such as lithography using ArF excimer laser light, EUV, or electron rays can be used. Exposure conditions such as a dose etc. are appropriately selected depending on the composition of the photoresist composition, the kind of additive, etc. As described above, this photoresist pattern forming method may include two or more exposure steps, and these two or more exposure steps may be performed using the same light source or different light sources. However, the first exposure step is preferably performed using ArF excimer laser light.

After exposure, post exposure baking (PEB) is preferably performed. By performing PEB, the dissociation reaction of the acid-dissociable group in the photoresist composition is allowed to smoothly proceed. The heating condition for PEB is usually 30° C. to 200° C., preferably 50° C. to 170° C.

### [Step (3)]

In this step, the resist film exposed in the step (2) is developed with a developer to form a pattern. The developer to be used may be a developer containing an aqueous alkaline solution or a negative developer containing an organic solvent. The developer further contains a basic compound. When the developer contains a basic compound in addition to the organic solvent, insolubility of exposed area of the resist film to the developer improves, which makes it possible to reduce film loss. The term “negative developer” herein used refers to a developer that selectively dissolves and removes a low exposed area and an unexposed area. The content of the organic solvent in the developer is preferably 80 mass % or more, more preferably 90 mass % or more, even more preferably 100 mass %. When the content of the organic solvent in the developer is within the above specific range, dissolution contrast between an exposed area and an unexposed area can be improved, and as a result, a pattern having excellent lithography characteristics can be formed. It is to be noted that examples of a component other than the organic solvent include water and silicone oil.

Examples of the organic solvent include alcohol solvents, ether solvents, ketone organic solvents, amide solvents, ester organic solvents, and hydrocarbon solvents.

Examples of the alcohol solvent include, for example,

aliphatic monoalcohol solvents having 1 to 18 carbon atoms, such as 4-methyl-2-pentanol and n-hexanol;

alicyclic monoalcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether.

Examples of the ether solvent include, for example,

dialkyl ether solvents such as diethyl ether, dipropyl ether, dibutyl ether, dipentyl ether, diisoamyl ether, dihexyl ether, diheptyl ether;

cyclic ether solvents such as tetrahydrofuran and tetrahydropyran;

aromatic ring-containing ether solvents such as diphenyl ether and anisole.

Examples of the ketone solvent include, for example,

chain ketone solvents such as acetone, methyl ethyl ketone, methyl-n-propyl ketone, methyl-n-butyl ketone, diethyl ketone, methyl-iso-butyl ketone, 2-heptanone, ethyl-n-butyl ketone, methyl-n-hexyl ketone, di-iso-butyl ketone, trimethyl nonanone;

cyclic ketone solvents such as cyclopentanone, cyclohexanone, cycloheptanone, cyclooctanone, and methylcyclohexanone;

2,4-pentanedione, acetonylacetone, acetophenone and the like.

Examples of the amide solvent include N,N′-dimethylimidazolidinone, N-methylformamide, N,N-dimethylformamide, N,N-diethylformamide, acetamide, N-methylacetamide, N,N-dimethylacetamide, N-methylpropionamide, N-methylpyrrolidone and the like.

Examples of the ester solvent include, for example,

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyvalent carboxylic acid diester solvents such as diethyl oxalate;

carbonate solvents such as dimethyl carbonate and diethyl carbonate.

Examples of the hydrocarbon solvent include, for example,

aliphatic hydrocarbon solvents having 5 to 12 carbon atoms, such as n-pentane and n-hexane;

aromatic hydrocarbon solvents having 6 to 16 carbon atoms, such as toluene and xylene.

Of these, ether solvents, ketone solvents, and ester solvents are preferred, and n-butyl acetate, isopropyl acetate, amyl acetate, anisole, methyl ethyl ketone, methyl-n-butyl ketone, and methyl-n-amyl ketone are more preferred. These organic solvents may be used alone or in combination of two or more.

The basic compound contained in the developer is selected from the group consisting of an onium salt, a polymer containing an onium salt, a nitrogen-containing compound, a nitrogen-containing compound containing three or more nitrogen atoms, a basic polymer, and a phosphorus-based compound.

The onium salt refers to a salt generated by formation of a coordination bond between an organic component and a Lewis base. The kind of onium salt to be used is not particularly limited, and examples of the onium salt include an ammonium salt, a phosphonium salt, an oxonium salt, a sulfonium salt, a selenonium salt, a carbonium salt, a diazonium salt, and an iodonium salt which have cationic structures.

Further, the cation in the onium salt structure includes one having a positive charge on a heteroatom of a heteroaromatic ring.

The polymer containing an onium salt is a polymer having an onium salt structure in its side chain or main chain.

The basic polymer is a polymer having a proton acceptor group. The basic polymer usually includes a structural unit having a basic site, but may include another structural unit having no basic site. Further, the basic polymer may include only one kind of structural unit having a basic site, but may include two or more kinds of structural units having a basic site.

The compound to be used may be a compound disclosed in JP-A-2014-219487.

The nitrogen-containing compound contained in the developer interact with a polar group generated in the resist film due to the action of an acid so that insolubility of an exposed area to the organic solvent can further be improved. Here, the interaction between the nitrogen-containing compound and the polar group refers to an action in which the nitrogen-containing compound and the polar group react to form a salt or an ionic bond. The nitrogen-containing compound is preferably a compound represented by the above formula (1).

In the above formula (1), R¹ and R² are each independently a hydrogen atom, a hydroxyl group, a formyl group, an alkoxy group, an alkoxycarbonyl group, a chain hydrocarbon group having 1 to 30 carbon atoms, an alicyclic hydrocarbon group having 3 to 30 carbon atoms, an aromatic hydrocarbon group having 6 to 14 carbon atoms, or a group obtained by combining two or more of these groups, R³ is a hydrogen atom, a hydroxyl group, a formyl group, an alkoxy group, an alkoxycarbonyl group, an n-valent chain hydrocarbon group having 1 to 30 carbon atoms, an n-valent alicyclic hydrocarbon group having 3 to 30 carbon atoms, an n-valent aromatic hydrocarbon groups having 6 to 14 carbon atoms, or an n-valent group obtained by combining two or more of these groups, n is an integer of 1 or more, wherein when n is 2 or more, two or more R¹s and two or more R²s may be the same or different, respectively, and any two of R¹ to R³ may be linked to form a cyclic structure together with the nitrogen atom linked thereto.

Examples of the chain hydrocarbon group having 1 to 30 carbon atoms represented by R¹ and R² include a methyl group, an ethyl group, an n-propyl group, an i-propyl group, an n-butyl group, a 2-methylpropyl group, a 1-methylpropyl group and a t-butyl group, and the like.

Examples of the alicyclic hydrocarbon group having 3 to 30 carbon atoms represented by R¹ and R² include a cyclopropyl group, a cyclopentyl group, a cyclohexyl group, an adamantyl group, a norbornyl group, and the like.

Examples of the aromatic hydrocarbon group having 6 to 14 carbon atoms represented by R¹ and R² include a phenyl group, a tolyl group, and a naphthyl group, and the like.

Examples of the group formed by combining two or more of these groups represented by R¹ and R² include an aralkyl group having 6 to 12 carbon atoms such as a benzyl group, a phenethyl group, a naphthylmethyl group, and a naphthylethyl group.

Examples of the n-valent chain hydrocarbon group having 1 to 30 carbon atoms represented by R³ include groups obtained by removing (n−1) hydrogen atoms from the groups mentioned above as examples of the chain hydrocarbon group having 1 to 30 carbon atoms represented by R¹ or R².

Examples of the alicyclic hydrocarbon group having 3 to 30 carbon atoms represented by R³ include groups obtained by removing (n−1) hydrogen atoms from the groups mentioned above as examples of the alicyclic hydrocarbon group having 3 to 30 carbon atoms represented by R¹ or R².

Examples of the aromatic hydrocarbon group having 6 to 14 carbon atoms represented by R³ include groups obtained by removing (n−1) hydrogen atoms from the groups mentioned above as examples of the aromatic hydrocarbon group having 6 to 14 carbon atoms represented by R¹ or R².

Examples of the group obtained by combining two or more of these groups and represented by R³ include groups obtained by removing (n−1) hydrogen atoms from the groups mentioned above as examples of the group obtained by combining two or more of these groups and represented by R¹ or R².

The groups represented by R¹ to R³ may be substituted. Specific examples of the substituent include a methyl group, an ethyl group, a propyl group, an n-butyl group, a t-butyl group, a hydroxyl group, a carboxy group, a halogen atom, and an alkoxy group. Examples of the halogen atom include a fluorine atom, a chlorine atom, and a bromine atom. Examples of the alkoxy group include a methoxy group, an ethoxy group, a propoxy group, and a butoxy group.

Examples of the compound represented by the above formula (1) include (cyclo)alkylamine compounds, nitrogen-containing heterocyclic compounds, amide group-containing compounds, urea compounds and the like.

Examples of the (cyclo)alkylamine compounds include a compound having one nitrogen atom, a compound having two nitrogen atoms, a compound having three or more nitrogen atoms and the like.

Examples of the (cyclo)alkylamine compounds having one nitrogen atom include:

mono(cyclo)alkylamines such as n-hexylamine, n-heptylamine, n-octylamine, n-nonylamine, 1-aminodecane, cyclohexylamine;

di(cyclo)alkylamines such as di-n-butylamine, di-n-pentylamine, di-n-hexylamine, di-n-heptylamine, di-n-octylamine, di-n-nonylamine, di-n-decylamine, cyclohexylmethylamine, dicyclohexylamine;

tri(cyclo)alkylamines such as triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, cyclohexyldimethylamine, methyldicyclohexylamine and tricyclohexylamine;

substituted alkylamines such as triethanolamine;

aromatic amines such as aniline, N-methylaniline, N,N-dimethylaniline, 2-methylaniline, 3-methylaniline, 4-methylaniline, N,N-dibutylaniline, 4-nitroaniline, diphenylamine, triphenylamine, naphthylamine, 2,4,6-tri-tert-butyl-N-methylaniline, N-phenyldiethanolamine, 2,6-diisopropylaniline, 2-(4-aminophenyl)-2-(3-hydroxyphenyl)propane, 2-(4-aminophenyl)-2-(4-hydroxyphenyl) propane.

Examples of the (cyclo)alkylamine compound having two nitrogen atoms include ethylenediamine, tetramethylethylenediamine, tetramethylenediamine, hexamethylenediamine, 4,4′-diaminodiphenylmethane, 4,4′-diaminodiphenylether, 4,4′-diaminobenzophenone, 4,4′-diaminodiphenylamine, 2,2-bis(4-aminophenyl)propane, 2-(3-aminophenyl)-2-(4-aminophenyl)propane, 1,4-bis[1-(4-aminophenyl)-1-methylethyl] benzene, 1,3-bis[1-(4-aminophenyl)-1-methylethyl]benzene, bis(2-dimethylaminoethyl)ether, bis(2-diethylaminoethyl)ether, 1-(2-hydroxyethyl)-2-imidazolidinone, 2-quinoxalinol, N,N,N′,N′-tetrakis(2-hydroxypropyl)ethylenediamine, and the like.

Examples of the (cyclo)alkylamine compound having three or more nitrogen atoms include polymers such as polyethyleneimine, polyallylamine, and 2-dimethylaminoethylacrylamide.

Examples of the nitrogen-containing heterocyclic compound include a nitrogen-containing aromatic heterocyclic compound and a nitrogen-containing aliphatic heterocyclic compound.

Examples of the nitrogen-containing aromatic heterocyclic compound include, for example,

imidazoles such as imidazole, 4-methylimidazole, 4-methyl-2-phenylimidazole, benzimidazole, 2-phenylbenzimidazole, 1-benzyl-2-methylimidazole, 1-benzyl-2-methyl-1H-imidazole;

pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, acridine, and 2,2′:6′,2″-terpyridine.

Examples of the nitrogen-containing aliphatic heterocyclic compound include, for example,

piperazines such as piperazine and 1-(2-hydroxyethyl)piperazine;

pyrazine, pyrazole, pyridazine, quinosaline, purine, pyrrolidine, proline, piperidine, piperidineethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, 1,4-diazabicyclo[2.2.2]octane, and the like.

Examples of the amide group-containing compound include, for example,

N-t-butoxycarbonyl group-containing amino compounds such as N-t-butoxycarbonyldi-n-octylamine, N-t-butoxycarbonyldi-n-nonylamine, N-t-butoxycarbonyldi-n-decylamine, N-t-butoxycarbonyldicyclohexylamine, N-t-butoxycarbonyl-1-adamantylamine, N-t-butoxycarbonyl-2-adamantylamine, N-t-butoxycarbonyl-N-methyl-1-adamantylamine, (S)-(−)-1-(t-butoxycarbonyl)-2-pyrrolidinemethanol, (R)-(+)-1-(t-butoxycarbonyl)-2-pyrrolidinemethanol, N-t-butoxycarbonyl-4-hydroxypiperidine, N-t-butoxycarbonylpyrrolidine, N-t-butoxycarbonylpiperazine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonylhexamethylenediamine, N,N,N′,N′-tetra-t-butoxycarbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N′-di-t-butoxycarbonyl-1, 10-diaminodecane, N,N′-di-tert-butoxycarbonyl-1,12-diaminododecane, N,N′-di-tert-butoxycarbonyl-4,4′-diaminodiphenylmethane, N-t-butoxycarbonylbenzimidazole, N-t-butoxycarbonyl-2-methylbenzimidazole, N-t-butoxycarbonyl-2-phenylbenzimidazole;

formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, tris(2-hydroxyethyl) isocyanurate.

Examples of the urea compound include urea, methylurea, 1,1-dimethylurea, 1,3-dimethylurea, 1,1,3,3-tetramethylurea, 1,3-diphenylurea, and tri-n-butylthiourea.

Among these, (cyclo)alkylamine compounds and nitrogen-containing aliphatic heterocyclic compounds are preferable, and 1-aminodecane, di-n-octylamine, tri-n-octylamine, tetramethylethylenediamine, N,N-dibutylaniline, proline is more preferred.

If necessary, an appropriate amount of surfactant may be added to the developer. Examples of the surfactant that can be used include ionic or nonionic fluorine-based and/or silicon-based surfactants.

Examples of a development method include a method in which the substrate is immersed in a bath filled with the developer for a certain period of time (dipping method), a method in which the developer is allowed to be present on the surface of the substrate due to surface tension and to stand for a certain period of time (puddle method), a method in which the developer is sprayed onto the surface of the substrate (spray method), and a method in which the developer is discharged onto the substrate that is rotated at a constant speed while a developer discharge nozzle is scanned at a constant speed (dynamic dispensing method).

### [Step (4)]

This pattern forming method includes, after the step (3), the processing step (4) in which the pattern is processed with a processing liquid exhibiting acidity. The processing liquid exhibiting acidity in the processing step preferably contains at least one selected from the group consisting of hydrogen peroxide, carbonic acid, nitric acid, sulfuric acid, organic acids and organic acid salts. Further, the organic acid or organic acid salt is preferably at least one organic acid selected from the group consisting of oxalic acid, citric acid, succinic acid, ethylenediaminetetraacetic acid, tartaric acid, salicylic acid, formic acid, acetic acid, propionic acid, butyric acid, valeric acid, caproic acid, caprylic acid, lauric acid, myristic acid One or two selected from the group consisting of, palmitic acid, stearic acid, arachinic acid, benzoic acid, acrylic acid, adipic acid, malonic acid, malic acid, glycolic acid, phthalic acid, terephthalic acid, pimelic acid and fumaric acid, or a salt thereof. The processing with such a processing liquid makes it possible to form a pattern having few pattern defects.

The pH of the processing liquid exhibiting acidity is preferably 3 or higher but lower than 7, more preferably 4 or higher but lower than 6.5. If the pH is 3 or lower, for example, acid corrosion of pipes etc. is induced.

The processing liquid exhibiting acidity may contain an organic solvent. The use of an organic solvent as such a processing liquid makes it possible to efficiently wash away generated scum.

As the organic solvent used as the processing liquid, a hydrocarbon-based solvent, a ketone-based solvent, an ester-based solvent, an alcohol-based solvent, an amide-based solvent and the like are preferable. Of these, alcohol-based solvents and ester-based solvents are more preferable, and alcohol-based solvents are further preferable. Among the above alcohol-based solvents, monohydric alcohol solvents having 6 to 8 carbon atoms are particularly preferred.

Examples of the monohydric alcohol solvents having 6 to 8 carbon atoms include linear, branched or cyclic monohydric alcohols. Specific examples include 1-hexanol, 1-heptanol, 1-octanol, 4-methyl-2-pentanol, 2-hexanol, 2-heptanol, 2-octanol, 3-hexanol, 3-heptanol, 3-octanol, 4-octanol, benzyl alcohol and the like. Of these, 1-hexanol, 2-hexanol, 2-heptanol and 4-methyl-2-pentanol are preferred.

The components of the processing liquid may be used singly or in combination of two or more of them. The water content of the processing liquid is preferably 10 mass % or less, more preferably 5 mass % or less, even more preferably 3 mass % or less. When the water content of the processing liquid is 10 mass % or lower, excellent developability can be achieved. It is to be noted that a surfactant may be added to the processing liquid.

Examples of a rinsing method using the processing liquid include a method in which the processing liquid is continuously discharged onto the substrate rotating at a constant speed (spin coating method), a method in which the substrate is immersed in a bath filled with the processing liquid for a certain period of time (dipping method), and a method in which the processing liquid is sprayed onto the surface of the substrate (spraying method).

### <Photoresist Composition>

The photoresist composition used in the present embodiment contains a polymer [A] and an acid generator [B]. Further, the photoresist composition preferably contains a fluorine atom-containing polymer [C], an acid diffusion controller [D], and a solvent [E]. The photoresist composition may further contain another optional component as long as the effects of the present embodiment are not impaired. Hereinbelow, each of the components will be described in detail.

### <Polymer [A]>

The polymer [A] has a structural unit (I) including an acid-dissociable group that dissociates due to the action of an acid, and the solubility of the polymer [A] to the developer reduces due to the dissociation of the acid-dissociable group. Since the polymer [A] has the structural unit (I), the acid-dissociable group dissociates due to the action of an acid generated from the acid generator [B] by exposure so that a polar group such as a carboxyl group is generated. As a result, the solubility of the polymer [A] to the negative developer containing an organic solvent reduces so that an excellent resist pattern can be formed. Further, the nitrogen-containing compound contained in the developer used in the pattern forming method interacts with the polar group, which makes it possible to further reduce the solubility of the polymer [A] to the developer. As a result, film loss of the resist film can be reduced in the pattern forming step. The term “polar group” used herein refers to a group having high polarity, such as a carboxyl group, a hydroxyl group, an amino group, or a sulfo group. It is to be noted that the polymer [A] preferably has a structural unit (II) containing a lactone group or a cyclic carbonate group in addition to the structural unit (I) as long as the effects of the present embodiment are not impaired, and may have another structural unit such as a structural unit (III) containing a polar group. It is to be noted that in the polymer [A], each structural unit may have only one kind of structural unit or two or more kinds of structural units.

### [Structural Unit (I)]

The structural unit (I) contains an acid-dissociable group that dissociates due to the action of an acid. The structural unit (I) preferably has a group represented by the above formula (2). When the structural unit (I) has a group represented by the above formula (2), a carboxyl group having high polarity is generated in the resist film used in the pattern forming method due to the action of an acid. The carboxyl group interacts with the nitrogen-containing compound contained in the developer so that the solubility of exposed area of the resist film in the developer can further be reduced. This makes it possible to further reduce film loss in the exposed area and obtain a pattern that has a reduced LWR and sufficiently satisfies sensitivity, DOF, etc. Further, the structural unit (I) is more preferably a structural unit represented by the above formula (3).

In the above formula (2), R^{P} is an acid-dissociable group.

The acid-dissociable group represented by R^{p} is preferably a group represented by the above formula (4).

In the formula (4), R^{p1} to R^{p3} are each an alkyl group having 1 to 4 carbon atoms or an alicyclic hydrocarbon group having 4 to 20 carbon atoms, wherein the alkyl group and the alicyclic hydrocarbon group may have substituents, and R^{p2} and R^{p3} may be linked together to form a divalent alicyclic hydrocarbon group having 4 to 20 carbon atoms together with a carbon atom linked thereto.

Examples of the alkyl group having 1 to 4 carbon atoms represented by R^{p1} to R^{p3} include a methyl group, an ethyl group, an n-propyl group, an i-propyl group, an n-butyl group, a 2-methylpropyl group, a 1-methylpropyl group, t-butyl group and the like.

Examples of the alicyclic hydrocarbon group having 4 to 20 carbon atoms represented by R^{p1} to R^{p3} include:

a polyalicyclic hydrocarbon group having a bridged skeleton such as an adamantane skeleton or a norbornane skeleton; and

a monoalicyclic hydrocarbon group having a cycloalkane skeleton such as cyclopentane or cyclohexane. Some or all of the hydrocarbon atoms of these groups may be substituted with, for example, at least one linear, branched, or cyclic alkyl group having 1 to 10 carbon atoms.

It is preferred that R^{p1} is an alkyl group having 1 to 4 carbon atoms, and R^{p2} and R^{p3} are linked together to form a divalent group having an adamantane skeleton or a cycloalkane skeleton together with a carbon atom linked thereto.

The group represented by the above formula (2) may be linked at any position of the structural unit (I). For example, the group represented by the above formula (2) may directly be linked to the main chain of the polymer or may be linked to the side chain of the polymer.

The structural unit (I) is preferably a structural unit represented by the above formula (3), and examples of the structural unit represented by the above formula (3) include structural units represented by the following formulas (1-1) to (1-4).

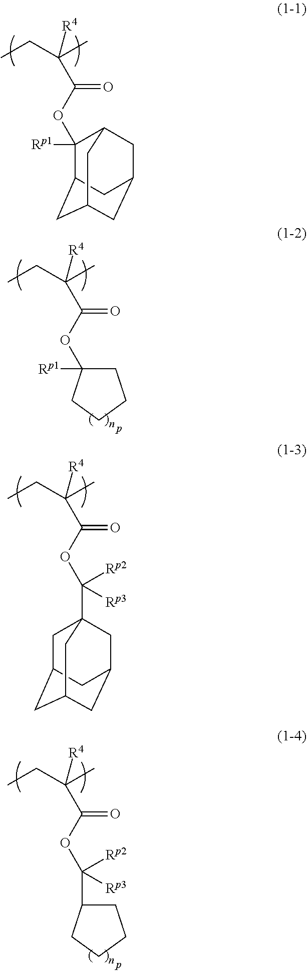

In the above formulas (1-1) to (1-4), R⁴ is the same as that defined in the above formula (3), R^{p1}, R^{p2}, and R^{p3} are the same as those defined in the above formula (4), and nₚ is an integer of 1 to 4.

The content of the structural unit (I) in the polymer [A] is preferably 20 mol % to 80 mol %, more preferably 30 mol % to 70 mol %. When the content of the structural unit (I) is within the above specific range, lithography characteristics at the time when the pattern forming method is used can further be improved.

### [Structural Unit (II)]

The polymer [A] preferably has a structural unit (II) containing a lactone group or a cyclic carbonate group. When the polymer [A] has the structural unit (II), adhesion of the resist film to the substrate in the pattern forming method can be improved. Here, the lactone group refers to a group containing one ring (lactone ring) having a structure represented by —O—C(O)—. The cyclic carbonate group refers to a group containing one ring (cyclic carbonate ring) having a structure represented by —O—C(O)—O—. The lactone ring or the cyclic carbonate ring is defined as a first ring, and therefore a group containing only a lactone ring or a cyclic carbonate ring is referred to as a monocyclic group, and a group further containing another cyclic structure is referred to as a polycyclic group irrespective of its structure.

Examples of the structural unit (II) include structural units represented by the following formulas.

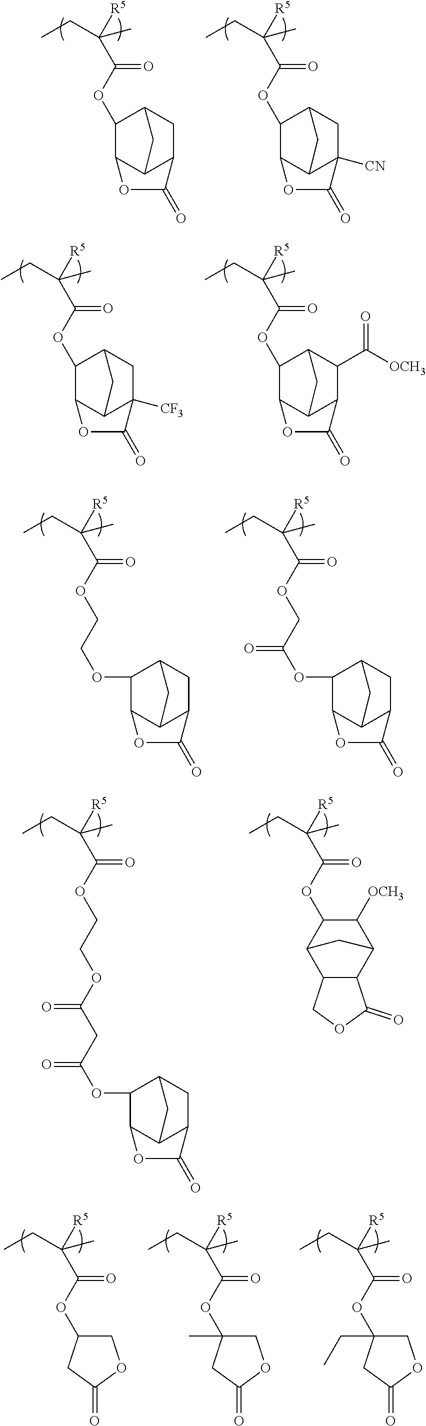

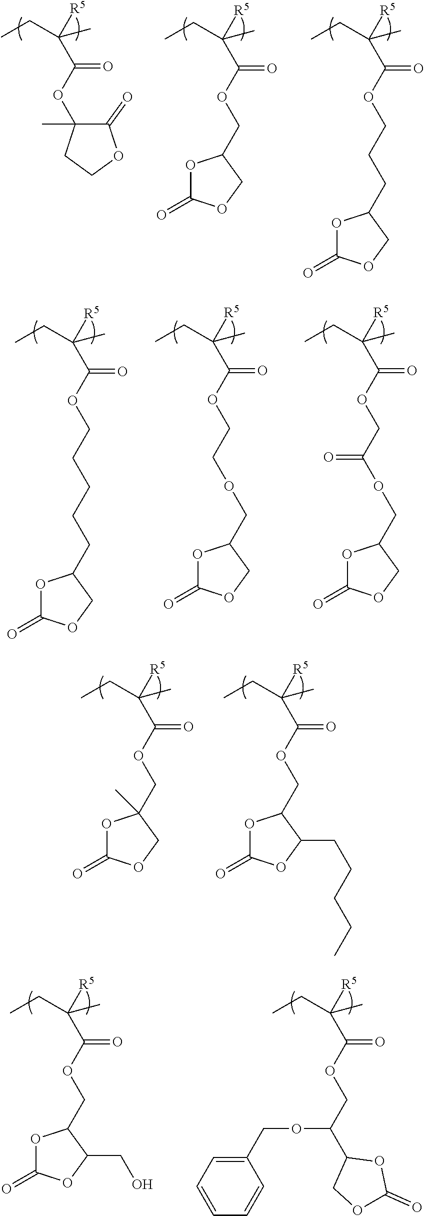

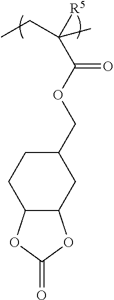

In the above formulas, R⁵ is a hydrogen atom, a fluorine atom, a methyl group, or a trifluoromethyl group.

Examples of a monomer that produces the structural unit (II) include monomers disclosed in WO 2007/116664 and a monomer represented by the following formula (5).

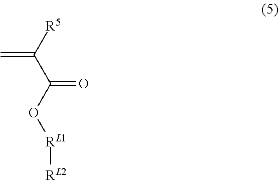

In the above formula (5), R⁵ is a hydrogen atom, a fluorine atom, a methyl group, or a trifluoromethyl group, R^{L1} is a single bond or a divalent linking group, and R^{L2} is a lactone group or a cyclic carbonate group.

Examples of the divalent linking group represented by R^{L1} include divalent linear or branched hydrocarbon groups having 1 to 20 carbon atoms.

Examples of the lactone group represented by R^{L2} include groups represented by the following formulas (L2-1) to (L2-6). Examples of the cyclic carbonate group represented by R^{L2} include groups represented by the following formulas (L2-7) and (L2-8).

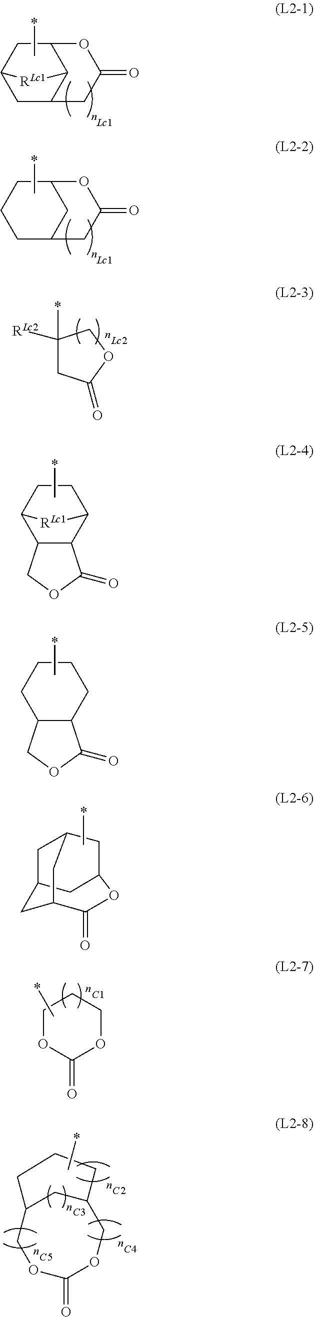

In the above formulas, R^{Lc1} is an oxygen atom or a methylene group, R^{Lc2} is a hydrogen atom or an alkyl group having 1 to 4 carbon atoms, n_{Lc1} is 0 or 1, n_{Lc2} is an integer of 0 to 3, n_{c1} is an integer of 0 to 2, n_{c2} to n_{c5} are each independently an integer of 0 to 2, and * represents a position at which R^{L1} in the above formula (5) is linked. It is to be noted that the groups represented by the above formulas (L2-1) to (L2-8) may have substituents.

The upper limit of content of the structural unit (II) in the polymer [A] is preferably 65 mol %, more preferably 55 mol %. The lower limit of content of the structural unit (II) in the polymer [A] is preferably 25 mol %, more preferably 35 mol %. When the content of the structural unit (II) is within the above specific range, adhesion of the resist film to the substrate or the like in the pattern forming method can further be improved.

The polymer [A] may have another structural unit other than the structural unit (I) and the structural unit (II). An example of the another structural unit includes a structural unit (III) containing a polar group.

### [Structural Unit (III)]

The polymer [A] preferably further has a structural unit (III) containing a polar group. When the polymer [A] further has the structural unit (III), miscibility between the polymer [A] and another component such as the acid generator [B] improves so that a pattern obtained by the pattern forming method can have more excellent lithography performance. Examples of the structural unit (III) include structural units represented by the following formulas.

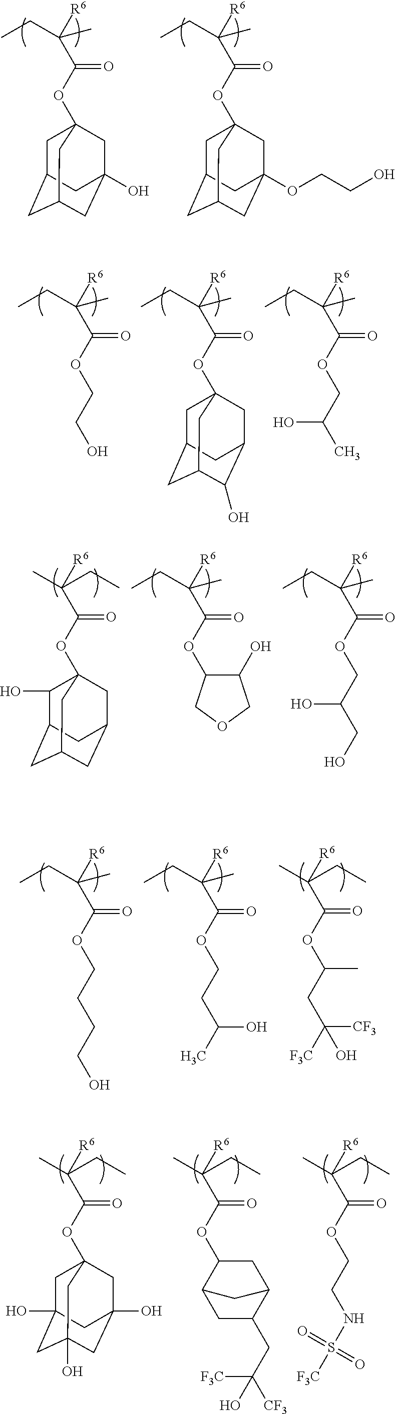

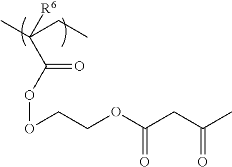

In the above formulas, R⁶ is a hydrogen atom, a fluorine atom, a methyl group, or a trifluoromethyl group.

The upper limit of content of the structural unit (III) in the polymer [A] is preferably 30 mold, more preferably 20 mol %.

### <Method for Synthesizing Polymer [A]>

The polymer [A] can be produced by, for example, polymerizing a monomer corresponding to each predetermined structural unit in an appropriate solvent with the use of a radical polymerization initiator. The polymer [A] is preferably synthesized by, for example, a method in which a solution containing a monomer and a radical initiator is dropped into a reaction solvent or a solution containing a monomer to cause a polymerization reaction, a method in which a solution containing a monomer and a solution containing a radical initiator are separately dropped into a reaction solvent or a solution containing a monomer to cause a polymerization reaction, or a method in which two or more kinds of solutions containing different monomers and a solution containing a radical initiator are separately dropped into a reaction solvent or a solution containing a monomer to cause a polymerization reaction.

Examples of the solvent used for the polymerization include, for example,

alkanes such as n-pentane, n-hexane, n-heptane, n-octane, n-nonane, n-decane;

cycloalkanes such as cyclohexane, cycloheptane, cyclooctane, decalin, norbornane;

aromatic hydrocarbons such as benzene, toluene, xylene, ethylbenzene and cumene;

halogenated hydrocarbons such as chlorobutane, bromohexane, dichloroethane, hexamethylene dibromide, chlorobenzene;

saturated carboxylic esters such as ethyl acetate, n-butyl acetate, i-butyl acetate and methyl propionate;

ketones such as acetone, 2-butanone, 4-methyl-2-pentanone and 2-heptanone;

ethers such as tetrahydrofuran, dimethoxyethanes and diethoxyethanes;

alcohols such as methanol, ethanol, 1-propanol, 2-propanol and 4-methyl-2-pentanol. These solvents may be used alone or in combination of two or more.

The reaction temperature of the polymerization is appropriately determined depending on the kind of radical initiator. The upper limit of the reaction temperature is usually 150° C., more preferably 120° C. or lower. The lower limit of the reaction temperature is preferably 40° C., more preferably 50° C. The reaction time is usually 48 hours or less, more preferably 24 hours or less. The lower limit of the reaction time is usually 1 hour.

Examples of the radical initiator used for the above polymerization include azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), 2,2′-azobis(2-methylpropionitrile) and the like. These initiators may be used as a mixture of two or more kinds.

The polymer obtained by the polymerization reaction is preferably collected by reprecipitation. More specifically, after the completion of the polymerization reaction, the polymer solution is poured into a reprecipitation solvent to collect a target resin as a powder. Examples of the reprecipitation solvent include alcohols and alkanes, and they may be used singly or in combination of two or more of them. Alternatively, the polymer may also be collected by removing low-molecular-weight components such as a monomer and an oligomer by a separation operation, a column operation, or ultrafiltration.

The lower limit of the weight-average molecular weight (Mw) of the polymer [A] determined by gel permeation chromatography (GPC) is preferably 1,000, more preferably 2,000. The upper limit of the Mw of the polymer [A] is preferably 10,000, more preferably 50,000, even more preferably 30,000. When the Mw of the polymer [A] is within the above specific range, film loss can be reduced, and a pattern having a reduced LWR can be obtained.

The ratio of the Mw to the number-average molecular weight of the polymer [A] (Mw/Mn) is usually 1 to 5. The upper limit of the ratio is preferably 3, more preferably 2. When the Mw/Mn is within such a specific range, a pattern having a reduced LWR can be obtained.

It is to be noted that the Mw and the Mn in this description refer to values measured by gel permeation chromatography (GPC) using GPC columns (G2000HXL×2, G3000HXL×1, and G4000HXL×1 manufactured by Tosoh Corporation), a differential refractometer as a detector, and monodisperse polystyrene standards under analysis conditions of a flow rate of 1.0 mL/min, an elution solvent of tetrahydrofuran, a sample concentration of 1.0 mass %, an amount of sample injected of 100 μL, and a column temperature of 40° C.

### <Radiation-Sensitive Acid Generator [B]>

The radiation-sensitive acid generator [B] generates an acid by exposure. The acid generated by exposure is considered to serve two functions in the photoresist composition depending on the strength thereof or pattern formation conditions. A first function of the acid generated by exposure is the function of dissociating the acid-dissociable group of the structural unit (I) of the polymer [A]. The radiation-sensitive acid generator having such a first function is referred to as a radiation-sensitive acid generator (I). A second function is the function of causing substantially no dissociation of the acid-dissociable group of the structural unit (I) of the polymer [A] but preventing the diffusion of an acid generated from the radiation-sensitive acid generator (I) in an unexposed area. The radiation-sensitive acid generator having such a second function is referred to as a radiation-sensitive acid generator (II). It can be said that an acid generated from the radiation-sensitive acid generator (II) is relatively weaker (has a larger pKa) than an acid generated from the radiation-sensitive acid generator (I). Whether the radiation-sensitive acid generator functions as a radiation-sensitive acid generator (I) or a radiation-sensitive acid generator (II) is determined by the strength of an acid generated, energy required to dissociate the acid-dissociable group of the structural unit (I) of the polymer [A], a heat energy condition when a pattern is formed using the photoresist composition, etc. The form of the radiation-sensitive acid generator [B] contained in the photoresist composition may be a compound that will be described later (hereinafter, also referred to as an “acid generating agent [B]”), a part of the polymer, or a combination of them.

When the radiation-sensitive acid generator (I) is contained, the polarity of the polymer [A] in an exposed area increases, and therefore when the developer is an aqueous alkaline solution, the polymer [A] in the exposed area is soluble in the developer, and on the other hand, when the developer is an organic solvent, the polymer [A] in the exposed area is hardly soluble in the developer.

When the radiation-sensitive acid generator (II) is contained, the photoresist composition can form a resist pattern more excellent in pattern developability and LWR performance.

Examples of the acid generator [B] include onium salts such as diazonium salts, phosphonium salts, sulfonium salts, iodonium salts, and pyridinium salts, imidosulfonates, oximesulfonates, diazosulfones, and disulfones.

Among these onium slats, sulfonium salts and iodonium salts are preferred.

These acid generators [B] may be used singly or in combination of two or more of them. When the acid generator [B] is an acid generating agent, the lower limit of the content of the acid generator [B] is usually 0.1 parts by mass, more preferably 0.5 parts by mass per 100 parts by mass of the polymer [A]. The upper limit of the content of the acid generator [B] is preferably 30 parts by mass, more preferably 20 parts by mass per 100 parts by mass of the polymer [A]. When the amount of the acid generator [B] to be used is within the above range, sensitivity and developability required of a resist can be achieved while transparency of the resist to radiation can be maintained.

### <Fluorine Atom-Containing Polymer [C]>

The fluorine atom-containing polymer (hereinafter, also referred to as a “polymer[C]”) is a polymer having a larger mass content of fluorine atoms than the polymer [A].

A polymer having higher hydrophobicity than a base polymer tends to be localized in the surface layer of a resist film. The polymer [C] has a larger mass content of fluorine atoms than the polymer [A], and therefore tends to be localized in the surface layer of the resist film due to characteristics resulting from the hydrophobicity thereof. As a result, it is possible to prevent elution of the acid generating agent, the acid diffusion controlling agent, etc. into an immersion medium in immersion exposure. Further, due to characteristics resulting from the hydrophobicity of the polymer [C], the advancing contact angle between the resist film and the immersion medium can be controlled to be within a desired range so that the occurrence of bubble defects can be prevented. Further, when the polymer [C] is contained, the receding contact angle between the resist film and the immersion medium increases, and therefore no water droplets remain and scanning exposure can be performed at a high speed. When the photoresist composition contains the polymer [C], a resist film suitable for immersion exposure can be formed.

The lower limit of the mass content of fluorine atoms in the polymer[C] is preferably 1 mass %, more preferably 2 mass %, even more preferably 3 mass %. The upper limit of the mass content is preferably 60 mass %, more preferably 50 mass %, even more preferably 40 mass %. When the mass content of fluorine atoms is within the above range, localization of the polymer [C] in the resist film can more appropriately be adjusted. It is to be noted that the mass content of fluorine atoms in the polymer can be calculated from the structure of the polymer determined by ¹³C-NMR spectroscopy.

The form of a fluorine atom contained in the polymer [C] is not particularly limited, and a fluorine atom may be linked to any of the main chain, side chain, and end of the polymer [C]. However, the polymer [C] preferably has a structural unit containing a fluorine atom (hereinafter, also referred to as a “structural unit (F)”).

### [Structural Unit (F)]

Examples of the structural unit (F) include structural units represented by the following formula (f-1).

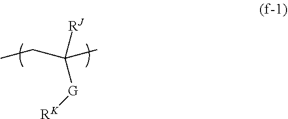

In the above formula (f-1), R^{J} is a hydrogen atom, a fluorine atom, a methyl group, or a trifluoromethyl group, G is a single bond, an oxygen atom, a sulfur atom, —COO—, —SO₂NH—, —CONH—, or —OCONH—, and R^{K} is a monovalent fluorinated chain hydrocarbon group having 1 to 6 carbon atoms or a monovalent fluorinated alicyclic hydrocarbon group having 4 to 20 carbon atoms.

The R^{J} is preferably a hydrogen atom or a methyl group, more preferably a methyl group from the viewpoint of copolymerizability of a monomer that produces the structural unit (f-1).

The G is preferably —COO—, —SO₂NH—, —CONH—, or —OCONH, more preferably —COO—.

Examples of the C1 to C6 monovalent fluorinated chain hydrocarbon group represented by R^{K} include C1 to C6 linear or branched alkyl groups whose some or all hydrogen atoms are substituted with fluorine atoms.

Examples of the monovalent fluorinated alicyclic hydrocarbon group having 4 to 20 carbon atoms represented by R^{K} include monocyclic or polycyclic hydrocarbon groups having 4 to 20 carbon atoms whose some or all hydrogen atoms are substituted with fluorine atoms.

The R^{k} is preferably a fluorinated chain hydrocarbon group, more preferably 2,2,2-trifluoroethyl group or 1,1,1,3,3,3-hexafluoro-2-propyl group, even more preferably 2,2,2-trifluoroethyl group.

When the polymer [C] has the structural unit (F), the lower limit of the content of the structural unit (F) is preferably 10 mol %, more preferably 20 mol with respect to the total amount of structural units constituting the polymer [C]. The upper limit of the content is preferably 100 mol %, more preferably 90 mol %. When the content of the structural unit (F) is within the above range, the mass content of fluorine atoms in the polymer [C] can more appropriately be adjusted.

The polymer [C] preferably has an alicyclic structure. An example of a structural unit (A) containing an alicyclic structure includes a structural unit containing a non-acid-dissociable alicyclic hydrocarbon group. Examples of the structural unit containing a non-acid-dissociable alicyclic hydrocarbon group include structural units represented by the following formula (7).

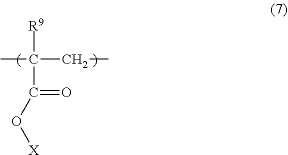

In the above formula (7), R⁹ is a hydrogen atom, a fluorine atom, a methyl group, or a trifluoromethyl group, and X is a monovalent alicyclic hydrocarbon group having 4 to 20 carbon atoms.

Examples of the monovalent alicyclic hydrocarbon group having 4 to 20 carbon atoms represented by X include hydrocarbon groups derived from alicyclic rings derived from cycloalkanes such as cyclobutane, cyclopentane, cyclohexane, bicyclo[2.2.1]heptane, bicyclo[2.2.2]octane, tricyclo[5.2.1.0^{2,6}]decane, tetracyclo[6.2.1.1^{3,6}0^{2,7}]dodecane, and tricyclo[3.3.1.1^{3,7}]decane. These hydrocarbon groups derived from alicyclic rings derived from cycloalkanes may have substituents, and may be substituted with, for example, one group or two or more groups that are the same or different in kind selected from linear or branched alkyl groups having 1 to 4 carbon atoms such as a methyl group, an ethyl group, an n-propyl group, an i-propyl group, an n-butyl group, a 2-methylpropyl group, a 1-methylpropyl group, and a t-butyl group and cycloalkyl groups having 3 to 10 carbon atoms. The substituents are not limited to these alkyl groups and cycloalkyl groups, and the hydrocarbon groups derived from alicyclic rings derived from cycloalkanes may be substituted with a hydroxyl group, a cyano group, a hydroxyalkyl group having 1 to 10 carbon atoms, a carboxyl group, or an oxygen atom.

When the polymer [C] has the structural unit (A), the lower limit of the content of the structural unit (A) is preferably 10 mol %, more preferably 30 mol %, even more preferably 50 mol % with respect to the total amount of structural units constituting the polymer [C]. The upper limit of the content is preferably 90 mol %, more preferably 80 mol %.

The polymer [C] may have a structural unit (B) containing an acid-dissociable group. An example of the structural unit (B) includes the structural unit (I) of the polymer W. The upper limit of the content of the structural unit [B] in the polymer [C] is preferably 20 mol %, more preferably 10 mol %, even more preferably 5 mol %, particularly preferably 0 mol % with respect to the total amount of structural units constituting the polymer [C].

When the photoresist composition contains the polymer [C], the lower limit of the content of the polymer[C] is preferably 0.1 parts by mass, more preferably 0.5 parts by mass, even more preferably 1 part by mass, particularly preferably 2 parts by mass per 100 parts by mass of the polymer [A]. The upper limit of the content is preferably 30 parts by mass, more preferably 20 parts by mass, even more preferably 15 parts by mass, particularly preferably 10 parts by mass. The photoresist composition may contain one or two or more kinds of polymers [C].

The polymer [C] can be synthesized by the same method as described above with reference to the polymer [A].

The lower limit of the Mw of the polymer [C] is preferably 1,000, more preferably 3,000, even more preferably 4,000. The upper limit of the Mw is preferably 50,000, more preferably 20,000, even more preferably 8,000.

The upper limit of the ratio of the Mw to the Mn (Mw/Mn) of the polymer [C] determined by GPC is preferably 5, more preferably 3, even more preferably 2, particularly preferably 1.5. The lower limit of the ratio is usually 1, preferably 1.2.

### <Acid Diffusion Controller [D]>

The acid diffusion controller [D] has the effect of controlling a phenomenon in which an acid generated from the acid generator [B] by exposure diffuses in the resist film and preventing an undesired chemical reaction in an unexposed area. When the photoresist composition contains the acid diffusion controller [D], the storage stability of the photoresist composition further improves, and the resolution of a resulting resist further improves. Further, it is possible to prevent a change in the line width of a resist pattern caused by a change in post-exposure delay that is the time between exposure and development, that is, it is possible to obtain a composition extremely excellent in process stability. It is to be noted that the form of the acid diffusion controller [D] contained in the photoresist composition according to the present embodiment may be a free compound (hereinafter, sometimes also referred to as an “acid diffusion controlling agent [D]”), a part of the polymer, or a combination of them.

Examples of the acid diffusion controlling agent [D] include an amine compound, an amide group-containing compound, a urea compound, and a nitrogen-containing heterocyclic compound.

Examples of the amine compound include: mono(cyclo)alkylamines; di(cyclo)alkylamines; tri(cyclo)alkylamines; substituted alkylanilines or derivatives thereof; ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis(1-(4-aminophenyl)-1-methylethyl)benzene, 1,3-bis(1-(4-aminophenyl)-1-methylethyl)benzene, bis(2-dimethylaminoethyl) ether, bis(2-diethylaminoethyl) ether, 1-(2-hydroxyethyl)-2-imidazolidinone, 2-quinoxalinol, N,N,N′,N′-tetrakis(2-hydroxypropyl)ethylenediamine, N,N,N′,N″,N″-pentamethyldiethylenetriamine, and triethanolamine.

Examples of the amide group-containing compound include N-t-butoxycarbonyl group-containing amino compound, formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, tris(2-hydroxyethyl) isocyanurate and the like.

Examples of the urea compound include urea, methylurea, 1,1-dimethylurea, 1,3-dimethylurea, 1,1,3,3-tetramethylurea, 1,3-diphenylurea, tri-n-butylthiourea and the like.

Examples of the nitrogen-containing heterocyclic compound include, for example, imidazoles; pyridines; piperazines; pyrazine, pyrazole, pyridazine, quinosaline, purine, pyrrolidine, piperidine, 4-hydroxy-N-amyloxycarbonylpiperidine, piperidineethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, 1,4-diazabicyclo[2.2.2]octane and the like.

As the acid diffusion controlling agent [D], a photodegradable base may be used which is photosensitive and generates a weak acid by exposure. The photodegradable base can have the function of the acid generating agent (II). That is, the photodegradable base generates an acid in an exposed area and increases the insolubility of the polymer [A] in the developer to prevent the surface roughness of the exposed area after development. On the other hand, the photodegradable base functions as a quencher in an unexposed area so that resolution can further be improved. An example of the photodegradable base includes an onium salt compound that loses acid diffusion controllability due to decomposition by exposure. Examples of the onium salt compound include a sulfonium salt compound represented by the following formula (D1) and an iodonium salt compound represented by the following formula (D2).

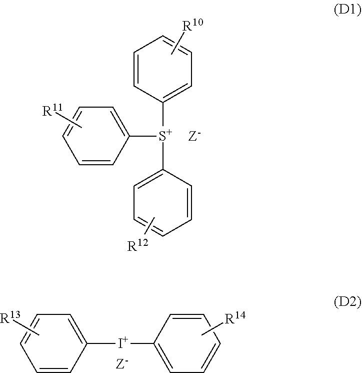

In the above formulas (D1) and (D2), R¹⁰ to R¹⁴ are each independently a hydrogen atom, an alkyl group, an alkoxy group, a hydroxyl group, a halogen atom, or —SO₂—R^{c}, R^{c} is an alkyl group, a cycloalkyl group, an alkoxy group, or an aryl group, Z— is OH—, R¹⁵—COO—, R^{D}—SO₂—N—R¹⁵, R¹⁵—SO₃—, or an anion represented by the following formula (D3), R¹⁵ is a linear or branched alkyl group having 1 to 10 carbon atoms, a cycloalkyl group having 3 to 20 carbon atoms, an aryl group having 6 to 30 carbon atoms, or an alkaryl group having 7 to 30 carbon atoms, wherein some or all hydrogen atoms of the alkyl group, the cycloalkyl group, the aryl group, and the alkaryl group may be substituted, R^{D} is a linear or branched alkyl group having 1 to 10 carbon atoms or a substituted or unsubstituted cycloalkyl group having 3 to 20 carbon atoms, wherein some or all hydrogen atoms of the alkyl group and the cycloalkyl group may be substituted with fluorine atoms, and when Z— is R¹⁵—SO₃—, a fluorine atom is not linked to a carbon atom linked to SO₃—.

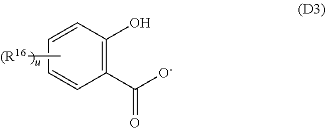

In the above formula (D3), R¹⁶ is a linear or branched alkyl group having 1 to 12 carbon atoms whose some or all hydrogen atoms may be substituted with fluorine atoms or a linear or branched alkoxy group having 1 to 12 carbon atoms, and u is an integer of 0 to 2.

The R¹⁰ to R¹⁴ in the above formulas (D1) and (D2) are each preferably a hydrogen atom or —SO₂—R^{c}. The R^{c} is preferably a cycloalkyl group, more preferably a cyclohexyl group.

Examples of the alkyl group represented by R¹⁵ include a methyl group, an ethyl group, a propyl group, an i-propyl group, a butyl group, an i-butyl group, a t-butyl group, and groups obtained by substituting some or all of hydrogen atoms of these groups.

Examples of the cycloalkyl group represented by R¹⁵ include a cyclopentyl group, a cyclohexyl group, a norbornyl group, a tricyclodecanyl group, a tetracyclododecanyl group, an adamantly group, and groups obtained by substituting some or all of the hydrogen atoms of these groups.

Examples of the aryl group represented by R¹⁵ include a phenyl group, a naphthyl group, an anthranyl group, and groups obtained by substituting some or all of the hydrogen atoms of these groups.

Examples of the alkaryl group represented by R¹⁵ include a benzyl group, a phenylethyl group, a phenylpropyl group, and groups obtained by substituting some or all of the hydrogen atoms of these groups.

Examples of substituents on the alkyl group, the cycloalkyl group, the aryl group, and the alkaryl group include a hydroxyl group, a halogen atom, an alkoxy group, a lactone group, and an alkylcarbonyl group.

Examples of the alkyl group represented by R^{D} include a methyl group, an ethyl group, a propyl group, and a butyl group.

Examples of the cycloalkyl group represented by R^{D} include a cyclopentyl group, a cyclohexyl group, a norbornyl group, and an adamantyl group.

Examples of the photodegradable base include compounds represented by the following formulas.

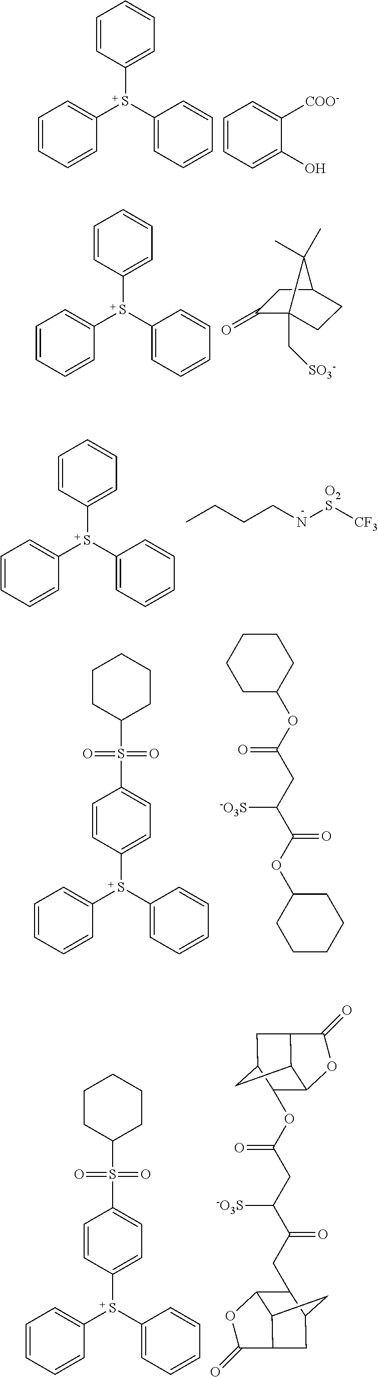

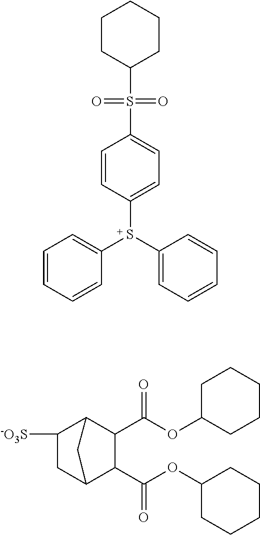

The amount of the acid diffusion controlling agent [D] contained in the photoresist composition used in the pattern forming method is preferably less than 10 parts by mass per 100 parts by mass of the polymer W. If the total amount of the acid diffusion controlling agents [D] used exceeds 10 parts by mass, the sensitivity of a resulting resist tends to reduce. These diffusion controlling agents [D] may be used singly or in combination of two or more of them.

### <Solvent [E]>

The photoresist composition used in the pattern forming method usually contains a solvent [E]. The solvent [E] is not particularly limited as long as at least the polymer [A], the acid generator [B], and the polymer [C], the acid diffusion controlling agent [D], and other optional components which are preferably contained can be dissolved. Examples of the solvent [E] include an alcohol-based solvent, an ether-based solvent, a ketone-based solvent, an amide-based solvent, an ester-based solvent, and a mixture of two or more of them.

Specific examples of the solvent [E] include the same organic solvents mentioned above with reference to the step (3) of the resist pattern forming method. Among them, propylene glycol monomethyl ether acetate, cyclohexanone, and γ-butyrolactone are preferred. These solvents may be used singly or in combination of two or more of them.

### <Other Optional Components>

The photoresist composition used in the pattern forming method may contain, as other optional components, a surfactant, an alicyclic skeleton-containing compound, a sensitizer, etc. It is to be noted that the photoresist composition may contain only one or two or more of the other optional components.

### [Surfactant]

The surfactant has an effect of improving the coatability, striation, developability, and the like of the photoresist composition used in the pattern forming method. Examples of the surfactant include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol stearate. Other examples include, as a product name, KP341 (Shin-Etsu Chemical Co., Ltd.) and POLYFLOW No. 75, POLYFLOW No. 95 (Kyoeisha Chemical Co., Ltd.), EFTOP EF301, EFTOP EF303, EFTOP EF352 (Tochem Products), Megafac F171, Megafac F173 (Dai Nippon Ink and Chemicals, Inc.), Fluorad FC430, Fluorad FC431 (Sumitomo 3M), AsahiGuard AG710, Surflon S-382, Surflon SC-101, Surflon SC-102, Surflon SC-103, Surflon SC-104, Surflon SC-105, Surflon SC-106 (Asahi Glass Industry) Company)

### [Alicyclic Skeleton-Containing Compound]

The alicyclic skeleton-containing compound has an effect of improving the dry etching resistance, pattern shape, adhesion to a substrate and the like of the photoresist composition used in the pattern forming method.

Examples of the alicyclic skeleton-containing compound include:

adamantane derivatives, including 1-adamantane carboxylic acid, 2-adamantanone, and t-butyl 1-adamantane carboxylate;

deoxycholic acid esters, including t-butyl deoxycholate, t-butoxycarbonylmethyl deoxycholate, and 2-ethoxyethyl deoxycholate;

lithocholic acid esters, including t-butyl lithocholate, t-butoxycarbonylmethyl lithocholate, and 2-ethoxyethyl lithocholate; and

3-[2-hydroxy-2,2-bis(trifluoromethyl)ethyl]tetracyclo[4.4.0.12,5.17,10]dodecane, and 2-hydroxy-9-methoxycarbonyl-5-oxo-4-oxa-tricyclo[4.2.1.03,7]nonane. The alicyclic skeleton-containing compound may be used alone, or two or more alicyclic skeleton-containing compounds may be used in combination.

### [Sensitizer]

The sensitizer shows an action of increasing the production of the acid, for example, from the acid generator [B], and has an effect of improving the “apparent sensitivity” of the photoresist composition used in the pattern forming method.

Examples of the sensitizer include carbazoles, acetophenones, benzophenones, naphthalenes, phenols, biacetyl, eosin, rose bengal, pyrenes, anthracenes, and phenothiazines. The sensitizer may be used alone, or two or more sensitizers may be used in combination.

### <Method for Preparing Photoresist Composition>

The photoresist composition used in the pattern forming method can be prepared by, for example, mixing the polymer[A], the acid generator [B], the polymer [C], the acid diffusion controlling agent [D], and the optional component(s) in a predetermined ratio in the solvent [E]. The photoresist composition can be prepared and used in a state where it is dissolved or dispersed in the solvent [E].

### <Developer>

The developer is a negative developer suitably used in the pattern forming method, and contains an organic solvent and a nitrogen-containing compound. It is to be noted that the description about the developer used in the step (3) of the pattern forming method can be applied to the developer.

### EXAMPLES

Hereinbelow, the present invention will specifically be described on the basis of examples, but is not limited to these examples. Various physical values were measured by the following methods.

### [Weight-Average Molecular Weight (Mw) and Number-Average Molecular Weight (Mn)]]

The Mw and Mn of a polymer were measured by gel permeation chromatography (GPC) using GPC columns manufactured by Tosoh Corporation (G2000HXL×2, G3000HXL×1, G4000HXL×1) under the following conditions.

Eluant: tetrahydrofuran (manufactured by Wako Pure Chemical Industries, Ltd.)

Flow rate: 1.0 mL/min

Sample concentration: 1.0 mass %

Amount of sample injected: 100 μL

Detector: differential refractometer

Standard material: monodisperse polystyrene

### [Content of Low-Molecular-Weight Components]

The content (mass %) of low-molecular-weight components (components having a molecular weight of less than 1,000) in a polymer [A] was measured by high-performance liquid chromatography (HPLC) using Inertsil ODS-25 μm column (4.6 mmφ×250 mm) manufactured by GL Sciences Inc. under the following conditions.

Eluant: acrylonitrile/0.1% aqueous phosphoric acid solution

Flow rate: 1.0 mL/min

Sample concentration: 1.0 mass %

Amount of sample injected: 100 μL

Detector: differential refractometer

### [¹³C-NMR Analysis]

¹³C-NMR analysis was performed using JNM-EX400 manufactured by JEOL Ltd. and DMSO-d6 as a solvent. The content of each structural unit in a polymer was calculated from the area ratio of a peak corresponding to each structural unit in a spectrum obtained by ¹³C-NMR.

### <Synthesis of Polymers [A]>

The following monomers were used to synthesize polymers [A] and polymers [C] that will be described later.

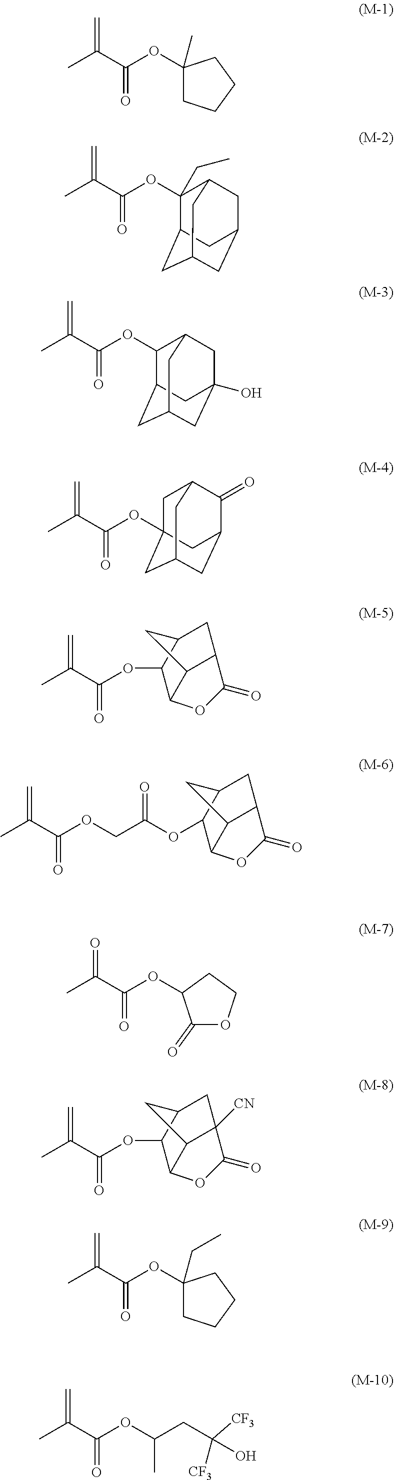

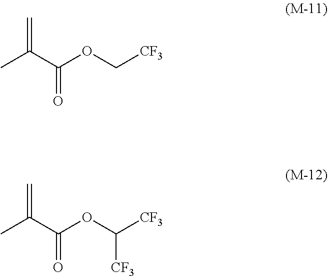

### Synthesis Example 1

43.08 g (50 mol %) of a compound (M-1) and 56.92 g (50 mol %) of a compound (M-5) were dissolved in 200 g of 2-butanone, and 4.21 g (5 mol % with respect to the total amount of the monomer compounds) of AIBN was added thereto to prepare a monomer solution. A 1000-mL three-necked flask containing 100 g of 2-butanone was purged with nitrogen for 30 minutes and then heated to 80° C. with stirring. The prepared monomer solution was added dropwise to the flask with a dropping funnel for 3 hours. A polymerization reaction was started from the start of dropping and performed for 6 hours. After the completion of the polymerization reaction, the polymerization solution was cooled with water to 30° C. or lower. The cooled polymerization solution was poured into 2,000 g of methanol, and a precipitated white powder was separated by filtration. The separated white powder was washed with 400 g of methanol twice and then collected by filtration and dried at 50° C. for 17 hours to obtain a white powdery polymer (A-1) (amount: 73 g, yield: 73%). The obtained polymer (A-1) had a Mw of 7,730, a Mw/Mn of 1.51, and a low-molecular-weight component content of 0.05 mass %. As a result of ¹³C-NMR analysis, the ratio between the content of a structural unit (I) derived from the compound (M-1) and the content of a structural unit (II) derived from the compound (M-5) in the polymer (A-1) was 47.3 (mol %):52.7 (mol %).

### Synthesis Examples 2 to 4

Polymers (A-2) to (A-4) were obtained in the same manner as in Synthesis Example 1 except that predetermined amounts of monomers shown in Table 1 were blended. The content of each structural unit, Mw, Mw/Mn ratio, yield (%), and low-molecular-weight component content of each of the obtained polymers are also shown in Table 1.

### Synthesis of Fluorine Atom-Containing Polymers [C]

### Synthesis Example 5

71.67 g (70 mol %) of a compound (M-9) and 28.33 g (30 mol %) of a compound (M-11) were dissolved in 100 g of 2-butanone, and 10.35 g of dimethyl 2,2′-azobisisobutyrate was added thereto to prepare a monomer solution. A 1000-mL three-necked flask containing 100 g of 2-butanone was purged with nitrogen for 30 minutes and then heated to 80° C. with stirring. The prepared monomer solution was added dropwise to the flask with a dropping funnel for 3 hours. A polymerization reaction was started from the start of dropping and performed for 6 hours. After the completion of the polymerization reaction, the polymerization solution was cooled with water to 30° C. or lower. The reaction solution was transferred into a 4-L separating funnel, and then the polymerization solution was homogeneously diluted with 300 g of n-hexane, and 1,200 g of methanol was poured thereinto and mixed therewith. Then, 60 g of distilled water was poured thereinto, and the resulting solution was stirred and allowed to stand for 30 minutes. Then, the lower layer was collected to prepare a propylene glycol monomethyl ether acetate solution (yield: 60%). The obtained polymer (C-1) had a Mw of 7,200, a Mw/Mn of 2.00, and a low-molecular-weight component content of 0.07 mass %. As a result of ¹³C-NMR analysis, the ratio between the content of a structural unit derived from the compound (M-9) and the content of a structural unit derived from the compound (M-11) in the polymer (C-1) was 71.1 mol %:28.9 mol %.

### Synthesis Example 6

A polymer (C-2) was obtained in the same manner as in Synthesis Example 5 except that predetermined amounts of monomers shown in Table 1 were blended. The content of a structural unit derived from each monomer compound, Mw, Mw/Mn ratio, yield (%), and low-molecular-weight component content of each of the obtained polymers are also shown in Table 1.

TABLE 1

| | | | | | | | | Low- |
|---|---|---|---|---|---|---|---|---|
| | | | | | | | | molecular- |
| | | Monomer | | | | | | weight |
| | | | Charge | | Content of each | | | component |
| | | | ratio | Yield | structural unit | | | content |
| | Polymer | Kind | (mol %) | (%) | (mol %) | Mw | Mw/Mn | (mass %) |
| Synthesis | A-1 | M-1/M-5 | 50/50 | 73 | 47/53 | 7,730 | 1.51 | 0.05 |
| Example 1 | | | | | | | | |
| Synthesis | A-2 | M-2/M-3/M-6 | 50/10/40 | 65 | 57/11/42 | 7,410 | 1.62 | 0.06 |
| Example 2 | | | | | | | | |
| Synthesis | A-3 | M-1/M-4/M-7 | 50/10/40 | 76 | 50/10/40 | 7,610 | 1.55 | 0.05 |
| Example 3 | | | | | | | | |
| Synthesis | A-4 | M-1/M-2/M-8 | 45/15/40 | 70 | 45/15/40 | 7,530 | 1.52 | 0.05 |
| Example 4 | | | | | | | | |
| Synthesis | C-1 | M-9/M-11 | 70/30 | 60 | 71/29 | 7,200 | 2.00 | 0.07 |
| Example 5 | | | | | | | | |
| Synthesis | C-5 | M-10/M-12 | 30/70 | 62 | 30/70 | 7,080 | 1.89 | 0.07 |
| Example 6 | | | | | | | | |

### <Preparation of Developers>

The following nitrogen-containing compounds were used to prepare developers.

### (Nitrogen-Containing Compounds)

(F-1): tri-n-octylamine

(F-2): di-n-octylamine

(F-3): 1-aminodecane

(F-4): N,N-dibutylaniline

(F-5): proline

(F-6): tetramethylethylenediamine

### Preparation Example 1

0.1 g (0.1 mass %) of a nitrogen-containing compound (F-1) was added to 99.9 g (99.9 mass %) of methyl-n-amyl ketone, and the mixture was stirred to obtain a developer (G-1).

### Preparation Examples 2 to 15

Developers (G-2) to (G-14) and (g-1) were obtained in the same manner as in Preparation Example 1 except that a predetermined amount of organic solvent and a predetermined amount of nitrogen-containing compound shown in Table 2 were blended.

TABLE 2

| | | | | Nitrogen- | |
|---|---|---|---|---|---|
| | | | | containing | |
| | | Organic solvent | | compound | |
| | | | Amount | | Amount |
| | | | used | | used |
| | Developer | Kind | (mass%) | Kind | (mass%) |
| Preparation | G-1 | methyl-n-amyl | 99.9 | F-1 | 0.1 |
| Example 1 | ketone | | | | |
| Preparation | G-2 | methyl-n-amyl | 99.0 | F-1 | 1.0 |
| Example 2 | ketone | | | | |
| Preparation | G-3 | methyl-n-amyl | 90.0 | F-2 | 10.0 |
| Example 3 | ketone | | | | |
| Preparation | G-4 | methyl-n-amyl | 98.0 | F-3 | 2.0 |
| Example 4 | ketone | | | | |
| Preparation | G-5 | methyl-n-amyl | 98.0 | F-4 | 2.0 |
| Example 5 | ketone | | | | |
| Preparation | G-6 | methyl-n-amyl | 98.0 | F-5 | 2.0 |
| Example 6 | ketone | | | | |
| Preparation | G-7 | methyl-n-amyl | 98.0 | F-1 | 2.0 |
| Example 7 | ketone | | | | |
| Preparation | G-8 | n-butyl acetate | 98.0 | F-4 | 2.0 |
| Example 8 | | | | | |
| Preparation | G-9 | n-butyl acetate | 98.0 | F-5 | 2.0 |
| Example 9 | | | | | |
| Preparation | G-10 | n-butyl acetate | 98.0 | F-2 | 2.0 |
| Example 10 | | | | | |
| Preparation | G-11 | anisole | 98.0 | F-3 | 2.0 |
| Example 11 | | | | | |
| Preparation | G-12 | anisole | 98.0 | F-5 | 2.0 |
| Example 12 | | | | | |
| Preparation | G-13 | anisole | 98.0 | F-4 | 2.0 |
| Example 13 | | | | | |
| Preparation | G-14 | methyl-n-amyl | 97.5 | F-6 | 2.5 |
| Example 14 | ketone | | | | |
| Preparation | g-1 | methyl-n-amyl | 100.0 | — | — |
| Example 15 | ketone | | | | |

The following processing liquids (H-1) to (H-3) were used as processing liquids exhibiting acidity.

(H-1) processing liquid containing hydrogen peroxide pH 6.6

(H-2) processing liquid containing carbonic acid pH 6.7

(H-3) processing liquid containing acetic acid pH 6.0

In each Example, processing was performed with the processing liquid exhibiting acidity, and then rinsing was performed with pure water for 7 seconds. In Comparative Examples, only rinsing with pure water was performed for 7 seconds without performing processing with the acidic processing liquid.

### <Preparation of Photoresist Compositions>

The following acid generator [B], acid diffusion controlling agent [D], and solvent [E] were used to prepare photoresist compositions.

### (Acid Generating Agent [B])

Compounds represented by the following formulas (B-1) and (B-2)

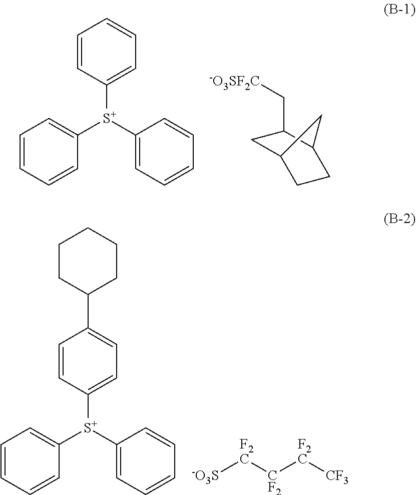

### (Acid Diffusion Controlling Agent [D])

Compounds represented by the following formulas (D-1) to (D-3)

(D-1): triphenylsulfonium camphorsulfonate

(D-2): 4-hydroxy-N-amyloxycarbonylpiperidine

(D-3): triethanolamine

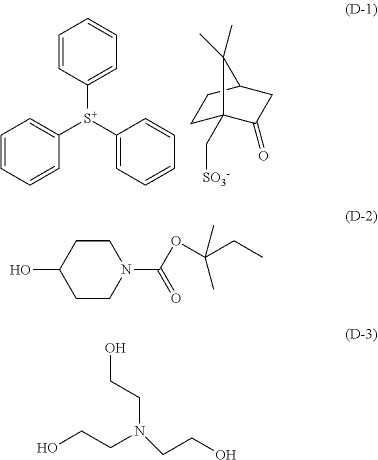

### (Solvent [E])

(E-1): propylene glycol monomethyl ether acetate

(E-2): cyclohexanone

(E-3): γ-butyrolactone

### Preparation Example 16

100 parts by mass of the polymer (A-1), 7.2 parts by mass of the acid generating agent (B-2), 3 parts by mass of the polymer (C-1), 3.9 parts by mass of the acid diffusion controlling agent (D-1), 2110 parts by mass of the solvent (E-1), 900 parts by mass of the solvent (E-2), and 30 parts by mass of the solvent (E-3) were mixed, and the resulting mixed solution was filtered through a filter having a pore diameter of 0.20 μm to prepare a photoresist composition (J-1).

### Preparation Examples 17 to 19

Photoresist compositions (J-2) to (J-4) were prepared in the same manner as in Preparation Example 16 except that the kinds and amounts of the components to be mixed were changed as shown in Table 3.

TABLE 3

| | | | | | | | | Acid diffusion | | | |
|---|---|---|---|---|---|---|---|---|---|---|---|
| | | | | Acid generating | | | | controlling | | | |
| | | Polymer [A] | | agent [B] | | Polymer [C] | | agent [D] | | | |
| | | | Amount | | Amount | | Amount | | Amount | | |
| | | | used | | used | | used | | used | Solvent [E] | |
| | | | (parts | | (parts | | (parts | | (parts | | Amount used |
| | Photoresist | | by | | by | | by | | by | | (parts by |
| | composition | Kind | mass) | Kind | mass) | Kind | mass) | Kind | mass) | Kind | mass) |
| Preparation | J-1 | A-1 | 100 | B-2 | 7.2 | C-1 | 3 | D-1 | 3.9 | E-1/E-2/E-3 | 2,110/900/30 |
| Example 16 | | | | | | | | | | | |
| Preparation | J-2 | A-2 | 100 | B-1 | 7.8 | C-2 | 3 | D-2 | 1.0 | E-1/E-2/E-3 | 2,110/900/30 |
| Example 17 | | | | | | | | | | | |
| Preparation | J-3 | A-3 | 100 | B-1 | 7.8 | C-1 | 3 | D-3 | 1.0 | E-1/E-2/E-3 | 2,150/940/30 |
| Example 18 | | | | | | | | | | | |
| Preparation | J-4 | A-4 | 100 | B-2 | 7.2 | C-2 | 3 | D-2 | 1.0 | E-1/E-2/E-3 | 2,150/940/30 |
| Example 19 | | | | | | | | | | | |

### Example 1

A lower antireflective film (ARC66 manufactured by Brewer Science) was applied onto a 12-inch silicon wafer with a spin coater (CLEAN TRACK Lithius Pro i manufactured by Tokyo Electron Ltd.), and heated at 205° C. for 60 seconds to form a lower antireflective film having a thickness of 105 nm. Then, the photoresist composition (J-1) was applied using the above spin coater, subjected to PB at 90° C. for 60 seconds, and cooled at 23° C. for 30 seconds to form a resist film having a thickness of 90 nm. Then, the resist film was exposed using an ArF immersion exposure apparatus (NSR-S610C manufactured by Nikon Precision) at NA=1.3 under best focus conditions and dipole illumination conditions. The exposure was performed using a ¼ projection scanner (NSR-S610C manufactured by Nikon Precision). The size on the reticle was 160 nm chromium/320 nm pitch, and the mask bias was 0 nm. Then, the resist film was subjected to PEB at 105° C. for 60 seconds on a hot plate (CLEAN TRACK Lithius pro i), cooled at 23° C. for 30 seconds, subjected to puddle development with the developer (G-1) for 30 seconds, and processed with the processing liquid (H-1) for 7 seconds. After rinsed with pure water, the silicon wafer was spin-dried at 2,000 rpm for 15 seconds to form a 40 nm line/80 nm pitch resist pattern.

### [Evaluation of Sensitivity]

An optimum dose such that a 40 nm line/80 nm pitch line pattern was formed by the above pattern forming method was defined as sensitivity (mJ/cm²). A case where the sensitivity was 60 (mJ/cm²) or less was evaluated as acceptable. It is to be noted that length measurement was performed using a scanning electron microscope (CG4000 manufactured by Hitachi High-Technologies Corporation). The results are shown in Table 5.

### [Evaluation of Depth of Focus (DOF)]

A resist film formed in the same manner as described above was exposed via a mask such that a 40 nm line/80 nm pitch line pattern was formed by reduced projection exposure. A focus fluctuation range when the line width of the line pattern formed was within 40 nm±10% was defined as depth of focus (DOF (nm)). A case where DOF was 300 (nm) or more was evaluated as acceptable because a DOF of 300 (nm) or more indicates that a change in patterning performance caused by a change in focus is small. The results are shown in Table 5.

### [Evaluation of Line Width Roughness (LWR)]

A 40 nm line/80 nm pitch line pattern formed in the same manner as described above was observed from the position above the pattern with a scanning electron microscope (CG4000 manufactured by Hitachi High-Technologies Corporation). The line width was measured at a total of 50 random points, and a variation in measured values was calculated as 3 sigma, which was defined as LWR (nm). A case where the LWR was 4.5 (nm) or less was evaluated as acceptable. The results are shown in Table 5.

### [Evaluation of Film Loss]

On an 8-inch silicon wafer having a 77 nm-thick lower antireflective film (ARC29A manufactured by Brewer Science), a resist film having an initial thickness of 120 nm was formed using the photoresist composition (J-1) and subjected to PB at 90° C. for 60 seconds. Then, the resist film was exposed without a mask by exposing the entire surface of the wafer at the above optimum dose using an ArF excimer laser exposure apparatus (NSR S306C manufactured by NIKON) at NA=0.78 and sigma=0.90 under conventional illumination conditions. After the exposure, the resist film was subjected to PEB at 105° C. for 60 seconds, subjected to puddle development with the developer (G-1) at 23° C. for 30 seconds, and processed with the processing liquid (H-1) for 7 seconds. After rinsed with pure water, the silicon wafer was spin-dried at 2,000 rpm for 15 seconds. After the completion of a series of the processes, the thickness of the remaining resist film was measured and subtracted from the initial thickness to determine the amount of film loss (nm). It is to be noted that the film thickness was measured using a spectrometric film thickness measurement system (Lambda Ace manufactured by Dainippon Screen Mfg. Co., Ltd.). A case where the amount of film loss measured was less than 30 nm was evaluated as acceptable, and a case where the amount of film loss measured was 30 nm or more was evaluated as unacceptable. The results are shown in Table 5.

### [Evaluation of Particle Defect]

A 40 nm line/80 nm pitch line pattern was formed in the same manner as described above. The formed resist pattern was inspected using a defect inspector (“KLA2905” manufactured by KLA-Tencor), and defect classification was performed using an electron beam review system (“eDR-7110” manufactured by KLA-Tencor). A case where the number of particle defects on the resist pattern was 10 or less was evaluated as (acceptable), and a case where the number of particle defects on the resist pattern was 11 or more was evaluated as (unacceptable). The results are shown in Table 5.

### Examples 2 to 16, Reference Examples 1 to 4, and Comparative Examples 1 to 7

The sensitivity, the depth of focus, the LWR, and the particle defect were evaluated in the same manner as in Example 1 except that the photoresist composition used, the PEB temperature, the PEB time, a combination of the developer and the processing liquid used were changed as shown in Table 4. In Table 4, “-” indicates that processing with the processing liquid was not performed. The results of various evaluations are shown in Table 5.

TABLE 4

| | | PEB | | | |
|---|---|---|---|---|---|
| | Photoresist | Temperature | Time | | Processing |
| | composition | (° C.) | (sec) | Developer | liquid |
| Example 1 | J-1 | 105 | 60 | G-1 | H-1 |
| Example 2 | J-1 | 105 | 60 | G-2 | H-1 |
| Example 3 | J-1 | 105 | 60 | G-3 | H-1 |
| Example 4 | J-1 | 105 | 60 | G-4 | H-1 |
| Example 5 | J-1 | 105 | 60 | G-5 | H-2 |
| Example 6 | J-1 | 105 | 60 | G-6 | H-2 |
| Example 7 | J-1 | 105 | 60 | G-7 | H-2 |
| Example 8 | J-1 | 105 | 60 | G-9 | H-2 |
| Example 9 | J-1 | 105 | 60 | G-10 | H-2 |
| Example 10 | J-1 | 105 | 60 | G-11 | H-3 |
| Example 11 | J-1 | 105 | 60 | G-12 | H-3 |
| Example 12 | J-1 | 105 | 60 | G-13 | H-3 |
| Example 13 | J-2 | 95 | 60 | G-2 | H-3 |
| Example 14 | J-3 | 105 | 60 | G-2 | H-3 |
| Example 15 | J-4 | 95 | 60 | G-2 | H-3 |
| Example 16 | J-1 | 90 | 60 | G-14 | H-3 |
| Reference | J-1 | 105 | 60 | g-1 | — |
| Example 1 | | | | | |
| Reference | J-2 | 95 | 60 | g-1 | — |
| Example 2 | | | | | |
| Reference | J-3 | 105 | 60 | g-1 | — |
| Example 3 | | | | | |
| Reference | J-4 | 95 | 60 | g-1 | — |
| Example 4 | | | | | |
| Comparative | J-1 | 105 | 60 | G-2 | — |
| Example 1 | | | | | |
| Comparative | J-1 | 105 | 60 | G-5 | — |
| Example 2 | | | | | |
| Comparative | J-1 | 105 | 60 | G-6 | — |
| Example 3 | | | | | |
| Comparative | J-1 | 105 | 60 | G-9 | — |
| Example 4 | | | | | |
| Comparative | J-1 | 105 | 60 | G-1 | — |
| Example 5 | | | | | |
| Comparative | J-3 | 105 | 60 | G-2 | — |
| Example 6 | | | | | |
| Comparative | J-4 | 95 | 60 | G-2 | — |
| Example 7 | | | | | |

TABLE 5

| | | | | | Particle |
|---|---|---|---|---|---|
| | | Amount of | | | defect |
| | Sensitivity | film loss | LWR | DOF | (number of |
| | (mJ/cm²) | (nm) | (nm) | (nm) | defects/wafer) |
| Example 1 | 42 | 24 | 4.3 | 330 | 7/acceptable |
| Example 2 | 46 | 22 | 4.2 | 300 | 8/acceptable |
| Example 3 | 40 | 23 | 4.1 | 300 | 4/acceptable |
| Example 4 | 50 | 28 | 4.2 | 300 | 5/acceptable |
| Example 5 | 48 | 28 | 4.1 | 300 | 9/acceptable |
| Example 6 | 48 | 22 | 4.1 | 300 | 7/acceptable |
| Example 7 | 48 | 23 | 4.1 | 300 | 2/acceptable |
| Example 8 | 28 | 18 | 4.1 | 350 | 9/acceptable |
| Example 9 | 30 | 18 | 4.1 | 350 | 1/acceptable |
| Example 10 | 38 | 20 | 4.1 | 330 | 5/acceptable |
| Example 11 | 38 | 19 | 4.2 | 330 | 9/acceptable |
| Example 12 | 38 | 19 | 4.2 | 360 | 4/acceptable |
| Example 13 | 38 | 28 | 4.2 | 330 | 2/acceptable |
| Example 14 | 27 | 26 | 4.2 | 360 | 9/acceptable |
| Example 15 | 36 | 25 | 4.2 | 380 | 8/acceptable |
| Example 16 | 44 | 20 | 4.2 | 300 | 1/acceptable |
| Reference | 58 | 43 | 4.8 | 330 | 2/acceptable |
| Example | 1 | | | | |
| Reference | 44 | 54 | 5.6 | 330 | 8/acceptable |
| Example | 2 | | | | |
| Reference | 45 | 46 | 5.7 | 330 | 4/acceptable |
| Example 3 | | | | | |
| Reference | 45 | 42 | 5.3 | 330 | 7/acceptable |
| Example 4 | | | | | |
| Comparative | 46 | 21 | 4.1 | 300 | 121/unacceptable |
| Example 1 | | | | | |
| Comparative | 48 | 28 | 4.1 | 300 | 93/unacceptable |
| Example 2 | | | | | |
| Comparative | 47 | 22 | 4.1 | 300 | 108/unacceptable |
| Example 3 | | | | | |
| Comparative | 28 | 18 | 4.1 | 350 | 65/unacceptable |
| Example 4 | | | | | |
| Comparative | 42 | 24 | 4.2 | 330 | 72/unacceptable |
| Example 5 | | | | | |
| Comparative | 27 | 26 | 4.2 | 360 | 81/unacceptable |
| Example 6 | | | | | |
| Comparative | 36 | 26 | 4.2 | 380 | 98/unacceptable |
| Example 7 | | | | | |

As shown in Table 5, the embodiment of the resist pattern forming method according to the present invention makes it possible to significantly reduce the film loss of a resist film during pattern formation and to reduce a variation in the line width of a resulting pattern and defects while maintaining excellent sensitivity and DOF. Further, the embodiment of the processing liquid according to the present invention makes it possible to reduce the film loss of a resist film during pattern formation, to reduce a variation in the line width of a resulting pattern while maintaining excellent sensitivity and DOF, and to significantly reduce development defects.

The embodiment of the resist pattern forming method according to the present invention makes it possible to reduce film loss in a resist pattern formation step and to reduce a variation in the line width of a resulting pattern and defects while maintaining excellent sensitivity and DOF. Further, the embodiment of the processing liquid according to the present invention makes it possible to reduce the film loss of a resist film during pattern formation, to reduce a variation in the line width of a resulting pattern while maintaining excellent sensitivity and DOF, and to significantly reduce development defects. Therefore, the embodiments of the pattern forming method and the processing liquid according to the present invention can suitably be used for resist pattern formation in the lithography step of various electronic devices such as semiconductor devices and liquid crystal devices.

Obviously, numerous modifications and variations of the present invention are possible in light of the above teachings. It is therefore to be understood that within the scope of the appended claims, the invention may be practiced otherwise than as specifically described herein.

What is claimed is:

1. A pattern forming method comprising:
applying a photoresist composition on a substrate to form a resist film on the substrate;
exposing the resist film;
developing the exposed resist film with a developer to form a pattern; and
contacting the pattern with a processing liquid to process the pattern, wherein
the photoresist composition comprises:
a polymer [A] having a structural unit (I) comprising an acid-dissociable group that dissociates due to action of an acid, the polymer having solubility to the developer that reduces due to dissociation of the acid-dissociable group; and
a radiation-sensitive acid generator [B], and
the processing liquid exhibits acidity.

2. The pattern forming method according to claim 1, wherein the developer comprises an organic solvent.

3. The pattern forming method according to claim 2, wherein the developer further comprises a basic compound.

4. The pattern forming method according to claim 3, wherein the basic compound is a nitrogen-containing compound.

5. The pattern forming method according to claim 4, wherein the nitrogen-containing compound is represented by following formula (1): 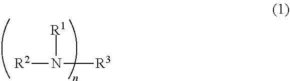
wherein:
R¹ and R² are each independently a hydrogen atom, a hydroxyl group, a formyl group, an alkoxy group, an alkoxycarbonyl group, a chain hydrocarbon group having 1 to 30 carbon atoms, an alicyclic hydrocarbon group having 3 to 30 carbon atoms, an aromatic hydrocarbon group having 6 to 14 carbon atoms, or a group obtained by combining two or more of the hydroxyl group, the formyl group, the alkoxy group, the alkoxycarbonyl group, the chain hydrocarbon group, the alicyclic hydrocarbon group, and the aromatic hydrocarbon group;
R³ is a hydrogen atom, a hydroxyl group, a formyl group, an alkoxy group, an alkoxycarbonyl group, an n-valent chain hydrocarbon group having 1 to 30 carbon atoms, an n-valent alicyclic hydrocarbon group having 3 to 30 carbon atoms, an n-valent aromatic hydrocarbon group having 6 to 14 carbon atoms, or an n-valent group obtained by combining two or more of the hydroxyl group, the formyl group, the alkoxy group, the alkoxycarbonyl group, the n-valent chain hydrocarbon group, the n-valent alicyclic hydrocarbon group, and the n-valent aromatic hydrocarbon group;
n is an integer of 1 or more, wherein when n is 2 or more, two or more R¹s and two or more R²s are the same or different, respectively, and any two of R¹ to R³ are optionally linked to form a cyclic structure together with the nitrogen atom linked thereto.

6. The pattern forming method according to claim 1, wherein the processing liquid comprises at least one selected from the group consisting of hydrogen peroxide, carbonic acid, nitric acid, sulfuric acid, an organic acid, and an organic acid salt.

7. The pattern forming method according to claim 6, wherein the processing comprises the organic acid or the organic acid salt, which is one or two or more organic acids selected from the group consisting of oxalic acid, citric acid, succinic acid, ethylenediamine tetra acetic acid, tartaric acid, salicylic acid, formic acid, acetic acid, propionic acid, butyric acid, valeric acid, caproic acid, caprylic acid, lauric acid, myristic acid, palmitic acid, stearic acid, arachic acid, benzoic acid, acrylic acid, adipic acid, malonic acid, malic acid, glycolic acid, phthalic acid, terephthalic acid, pimelic acid, and fumaric acid, and a salt thereof.

8. The pattern forming method according to claim 1, wherein the structural unit (I) of the polymer has a group represented by formula (2): 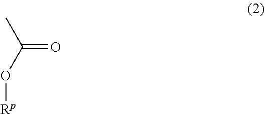
where R^{P} is an acid-dissociable group.

9. The pattern forming method according to claim 8, wherein the structural unit (I) is represented by formula (3): 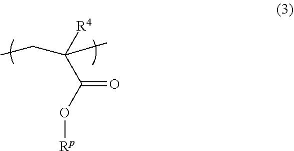
where R⁴ is a hydrogen atom, a methyl group, or a trifluoromethyl group, and R^{P} is as defined in the formula (2).

10. The pattern forming method according to claim 8, wherein the acid-dissociable group represented by R^{P} is a group represented by formula (4): 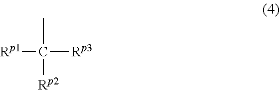
where R^{p1} to R^{P3} are each an alkyl group having 1 to 4 carbon atoms or an alicyclic hydrocarbon group having 4 to 20 carbon atoms, wherein some or all of hydrogen atoms of the alkyl group and the alicyclic hydrocarbon group are optionally substituted, and R^{P2} and R^{P3} are optionally linked together to form a divalent alicyclic hydrocarbon group having 4 to 20 carbon atoms together with the carbon atom linked thereto.

11. The pattern forming method according to claim 2, wherein the organic solvent contained in the developer is at least one selected from the group consisting of an ether-based solvent, a ketone-based solvent, and an ester-based solvent.

12. A processing liquid comprising at least one selected from the group consisting of hydrogen peroxide, carbonic acid, nitric acid, sulfuric acid, an organic acid, and an organic acid salt, the processing liquid exhibiting acidity and being suitable for processing in a pattern forming method comprising:
developing a resist film with a developer comprising an organic solvent and a basic compound; and
performing processing of a pattern formed in the step of developing.
